(19) United States
(12) Patent Application Publication
(10) Pub. No.: US 2010/0224998 A1
(43) Pub. Date: Sep. 9, 2010

(54) Integrated Circuit with Ribtan Interconnects

(75) Inventors: Steven Grant Duvall, Milsons (AU); Pavel Khokhlov, Moscow (RU); Pavel I. Lazarev, London (GB)

Correspondence Address: HOUST CONSULTING (Kont), P.O. BOX 2688, SARATOGA, CA, 95070-0688, US

(73) Assignee: Carben Semicon Limited, Nicosia (CY)

(21) Appl. No.: 12/492,125

(22) Filed: Jun. 25, 2009

Related U.S. Application Data
(60) Provisional application No. 61/076,053, filed on Jun. 26, 2008.

(51) Int. Cl. H01L 23/532; H01L 21/768

(52) U.S. Cl. 257/767; 438/618; 257/E23.165; 257/E21.582

(57) ABSTRACT

An integrated circuit (IC) includes an interconnect system made of electrically conducting ribtan material. The integrated circuit includes a substrate, a set of circuit elements that are formed on the substrate, an interconnect system that interconnects the circuit elements. At least part of the interconnect system is made of a metallic ribtan material.

### CROSS REFERENCE TO RELATED APPLICATIONS

This application is related to the following applications that are filed concurrently herewith.

United States patent application entitled “Patterned Integrated Circuit and Method of Production Thereof,” Attorney Docket 7006-0351; and

United States patent application entitled “Film and Device Using Layer Based on Ribtan Material,” Attorney Docket 7006-0401.

The disclosures of both of the above applications are incorporated herein by reference in their entirety.

### FIELD OF THE INVENTION

The present invention relates generally to integrated circuits (ICs) and more particularly to ICs in which the interconnect system is made of an electrically conducting ribtan material.

### BACKGROUND OF THE INVENTION

Integrated circuits are used to carry out a wide variety of tasks in many different electrical and electronic components. They form the basis for many electronic systems. An integrated circuit typically includes a large number of circuit elements such as transistors, diodes, and other active and passive circuit elements that are formed on a single semiconductor substrate and are interconnected to implement a desired function. These circuit elements are fabricated by forming layers of different materials and of different geometric shapes on various regions of the substrate. The increasing complexity of these integrated circuits requires the use of an ever-increasing number of linked transistors and other circuit elements. For instance, ultra-large scale integrated circuits may have more than a million logic gates on a single substrate.

The large number of active elements in a typical integrated circuit dictates a very large number of interconnections. Since these elements must be packaged within a small area, the widths of individual interconnections are limited and decreasing as the density of active elements increases. The resistance of copper interconnects, with cross-sectional dimensions on the order of the mean free path of electrons (˜40 nm in Cu at room temperature) in current and imminent technologies, is increasing rapidly with decreasing width under the combined effects of enhanced grain boundary scattering, surface scattering and the presence of the highly resistive diffusion barrier layer [see, W. Steinhogl et al., “Size-dependent Resistivity of Metallic Wires in the Mesoscopic Range,” Physical Review B, 66, 075414, 2002]. The steep rise in parasitic resistance of copper interconnects poses serious challenges for interconnect delay (especially at the global level where wires traverse long distances) and for interconnect reliability. Hence it has a significant impact on the performance and reliability of integrated circuits.

New interconnect materials are required to overcome these drawbacks. Indeed, the transition in the 1990's from aluminum to copper was motivated by the need to address similar problems in aluminum, which were preventing continued reduction in the widths of interconnections at that time. Carbon nanotubes have recently been proposed as a possible replacement for metal interconnects in the future technologies. Carbon nanotubes (CNT) are graphene sheets rolled up into cylinders with diameter on the order of a nanometer. There exist two kinds of carbon nanotubes. Multi-wall carbon nanotubes (MWCNT) are more common and are rolled-up stacks of graphene sheets in concentric carbon nanotubes. A single-wall carbon nanotube (SWCNT) is a rolled-up shell of graphene sheet made of benzene-type hexagonal carbon rings. SWCNT technology shows significant promise in acting as interconnects in future generations of ultra-large scale integrated circuits. Compared with the conventional metal interconnects, SWCNTs can sustain a high current density without electro-migration. In this manner, they show great potential for electronic applications. In addition, the SWCNTs can have very low resistance, overcoming the problem of increasing resistance as conventional metal interconnects are scaled down.

Electro-thermal transport in metallic single-wall carbon nanotubes for interconnect applications was studied by Eric Pop, David Mann, et al. in Laboratory for Advanced Materials, Chemistry and Thermal Sciences Department of Mechanical Engineering Stanford University (see, Electron Devices Meeting, 2005. IEDM Technical Digest. IEEE International 5-7 Dec. 2005, p. 4). This work studied the electro-thermal properties of metallic single-wall carbon nanotubes (SWNTs) in interconnect applications. Experimental data and careful modeling reveal that self-heating is of significance in short (1<L<10 μm) nanotubes under high-bias. The low-bias resistance of micron scale SWNTs is also found to be affected by optical phonon absorption (a scattering mechanism previously neglected) above 250 K. The authors also explore length-dependent electrical breakdown of SWNTs in ambient air.

Metallic carbon nanotube interconnects were studied by Chiariello, A. G., Maffucci, A., et al. in Signal Propagation on Interconnects, 2006, IEEE Workshop on. (9-12 May 2006), pp. 181-184. This paper illustrates the inclusion, in a 3D integral formulation of Maxwell equations, of a fluid model for the study of the electrodynamics of metallic carbon nanotubes in the frequency domain. The effective conduction electrons are modeled as an infinitesimally thin cylindrical layer of compressible fluid, whose dynamics are described by means of the linearized Euler's equation. The resulting integral equations are solved numerically by the finite element method, using the facet elements and the null-pinv decomposition. The proposed formulation is applied to study carbon nanotubes interconnects. In another paper of these authors (see Propagation on Interconnects, 2006, IEEE Workshop on. (9-12 May 2006), pp. 185-188) a transmission line model is derived to describe the propagation along single-wall carbon nano-tubes, candidate to be used as interconnects in nano-electronics applications. The model is obtained in a consistent way from a fluid model of the electron conduction along such a nanostructure. The per-unit-length parameters are strongly dependent on the effects related to the electron inertia and the quantum fluid pressure. The values of the signal propagation velocity, characteristic impedance and characteristic damping of the obtained transmission line are very different from that obtainable, in principle, by ideally scaling the conventional technology. A successful benchmark test with a full-wave model is presented and some case-studies are carried out to investigate the possibility to use such structures as interconnects in the future devices.

Performance comparison between carbon nanotubes and copper (Cu) for future high-performance on-chip interconnect applications was studied by Kyung-Hoae Koo, Hoyeol Cho, et al. in IEEE Transactions on Electron Devices, December 2007, vol. 54(12), pp. 3206-3215. Optical interconnects and carbon nanotubes (CNTs) present promising options for replacing the existing Cu-based global/semi-global (optics and CNT) and local (CNT) wires. The authors quantify the performance of these novel interconnects and compare it with Cu/low-kappa wires for future high-performance integrated circuits. The authors find that for a local wire, a CNT bundle exhibits a smaller latency than Cu for a given geometry. In addition, by leveraging the superior electro-migration properties of CNT and optimizing its geometry, the latency advantage can be further amplified. For semi-global and global wires, the authors compare both optical and CNT options with Cu in terms of latency, energy efficiency/power dissipation, and bandwidth density. The authors also compare the relationship between bandwidth density, power density, and latency, thus alluding to the latency and power loss to achieve a given bandwidth density. Optical wires have the lowest latency and the highest possible bandwidth density using wavelength division multiplexing, whereas a CNT bundle has a lower latency than Cu. The power density comparison is highly switching activity (SA) dependent, with high SA favoring optics. At low switching activity (SA), optics is only power efficient compared to CNT for a bandwidth density beyond a critical value. Finally, the authors also quantify the impact of improvement in optical and CNT technology on the above comparisons. A small monolithically integrated detector and modulator capacitance for optical interconnects (˜10 fF) yields a superior power density and latency even at relatively lower SA (˜20%) but at high bandwidth density. At lower bandwidth density and SA lower than 20%, an improvement in mean free path and packing density of CNT can render it most energy efficient.

Structural and electrical characterization of carbon nanofibers for interconnect via applications were studied by Quoc Ngo Yamada, T. Suzuki, M., et al. in IEEE Transactions on Electron Devices, November 2007), val. 6(6), pp. 688-695. The authors present temperature-dependent electrical characteristics of vertically aligned carbon nanofiber (CNF) arrays for on-chip interconnect applications. The study consists of three parts. First, the electron transport mechanisms in these structures are investigated using I-V measurements over a broad temperature range (4.4 K to 350 K). The measured resistivity in CNF arrays is modeled based on known graphite two-dimensional hopping electron conduction mechanism. The model is used because of the disordered graphite structure observed during high-resolution scanning transmission electron microscopy (STEM) of the CNF and CNF-metal interface. Second, electrical reliability measurements are performed at different temperatures to demonstrate the robust nature of CNFs for interconnect applications. Finally, some guidance in catalyst material selection is presented to improve the nanostructure of CNFs, making the morphology similar to multiwall nanotubes.

Analyzing conductance of mixed carbon-nanotube bundles for interconnect applications was performed in Electron Device Letters, IEEE (August 2008), 28(8), pp. 756-759. The study shows that the carbon-nanotube (CNT) bundle is a potential candidate for deep-nanometer-interconnect applications due to its superior conductivity and current-carrying capabilities. A CNT bundle is generally a mixture of single-wall and multiwall CNTs (SWCNTs and MWCNTs). The paper introduces a diameter-dependent model to analyze the conductance of both SWCNTs and MWCNTs. Using this model, the conductance performance of the mixed CNT bundles is analyzed, and the estimation is consistent with the corresponding experimental result. The authors also demonstrated that the mixed CNT bundles can provide two to five times conductance improvement over copper by selecting the suitable parameters such as bundle width, tube density, and metallic tube ratio.

Carbon nanotube devices for GHz to THz applications were studied by Peter J. Burke in Proc. of SPIE Vol. 5593, pp. 52-61. The author presents an overview of recent work aimed at advancing the understanding of this new field. Specifically, the authors discuss passive RF circuit models of one-dimensional nanostructures as interconnects.

Carbon nanotubes are better conductors than copper and do not face the same problems that exist in copper interconnects. However, it is difficult to imagine how nanotube interconnects could be seamlessly integrated into the integrated circuit fabrication process within the next few years as that would require hundreds of millions of nanotubes to be precisely placed and connected to transistors, vias and other elements of ICs. In addition, the substantial difference in size between transistors and nanotube interconnects complicates the fabrication process. And also, the electrical properties of the nanotubes will need to be precisely defined and controlled. Although the concept of using carbon nanotubes as interconnects is very attractive, the technical problems associated with this idea seem to be exceedingly difficult to overcome.

### SUMMARY OF THE INVENTION

The present invention provides an integrated circuit comprising a substrate, a set of circuit elements that are formed on the substrate, and an interconnect system that interconnects the circuit elements; at least part of the interconnect system is made of a metallic ribtan material.

In a further aspect, the present invention provides a method of producing a metallic ribtan layer on a substrate, which comprises the following steps: (a) application of a solution of at least one π-conjugated organic compound of a general structural formula I or a combination of the organic compounds of the general structural formula I on the substrate:

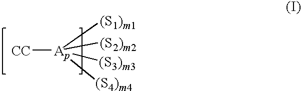

where CC is a predominantly planar carbon-conjugated core; A is a hetero-atomic group; p is 0, 1, 2, 3, 4, 5, 6, 7, or 8; S₁, S₂, S₃, and S₄ are substituents, m1, m2, m3 and m4 are 0, 1, 2, 3, 4, 5, 6, 7, or 8; and sum (m1+m2+m3+m4) is 1, 2, 3, 4, 5, 6, 7, 8, 9 or 10; (b) drying with formation of a solid precursor layer, and (c) formation of the metallic ribtan layer. Said formation step (c) is characterized by a level of vacuum, a composition and pressure of ambient gas, and a time dependence of temperature which are selected so as to ensure a creation of predominantly planar graphene-like structures in the metallic ribtan layer. At least one said graphene-like structure possesses conductivity and is predominantly continuous within the entire metallic ribtan layer, and wherein thickness of the metallic ribtan layer is in the range from approximately 1 nm to 1000 nm.

In still further aspect, the present invention provides a method of producing a metallic ribtan layer on a substrate, which comprises the following steps: (a) preparation of a solution of one π-conjugated organic compound of a general structural formula II or a combination of the organic compounds of the general structural formula II capable of forming supramolecules:

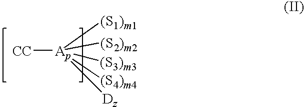

where CC is a predominantly planar carbon-conjugated core; A is an hetero-atomic group; p is 0, 1, 2, 3, 4, 5, 6, 7, or 8; S₁, S₂, S₃, S₄ and D are substituents, where S₁, S₂, S₃, and S₄ are substituents providing solubility of the organic compound in suitable solvent and D is a substituent which produces reaction centers selected from the list comprising free radicals and benzyne fragments on the predominantly planar carbon-conjugated cores after elimination this substituent during a step (e); m1, m2, m3 and m4 are 0, 1, 2, 3, 4, 5, 6, 7, or 8; sum (m1+m2+m3+m4) is 1, 2, 3, 4, 5, 6, 7, 8, 9 or 10, and z is 0, 1, 2, 3 or 4; (b) deposition a layer of the solution on the substrate; (c) an alignment action upon the solution in order to ensure preferred alignment of the supramolecules; (d) drying with formation of a solid precursor layer; and (e) applying an external action upon the solid layer stimulating low-temperature carbonization and formation of a metallic ribtan layer.

### BRIEF DESCRIPTION OF THE DRAWINGS

These and various other features and advantages of the present invention will become better understood upon reading of the following detailed description in conjunction with the accompanying drawings and the appended claims provided below, where:

FIG. 1 schematically shows a graphene-like carbon-based structure;

FIG. 2 schematically shows an anisotropic ribtan layer on a substrate after a step of formation of the metallic ribtan layer (carbonization process) where the planes of π-conjugated organic compound are oriented predominantly perpendicularly to the substrate surface;

FIG. 3 shows chemical formulas of six isomers of Bis (carboxybenzimidazoles) of Perylenetetracarboxylic acids;

FIG. 4 schematically shows the supramolecules on a substrate oriented along the y-axis;

FIG. 5 shows the typical time dependence of temperature during a formation step;

FIG. 6 shows the results of thermo-gravimetric analysis of the bis-carboxy DBI PTCA layer;

FIG. 7 schematically shows the intermediate anisotropic structure of carbon-conjugated residue formed after an initial carbonization process;

FIG. 8 shows a TEM image of the ribtan layer annealed at 650° C. for 30 minutes;

FIG. 9 shows electron diffraction on the ribtan layer annealed at 650° C. for 30 minutes;

FIG. 10 shows absorption spectra of the annealed and dried layer of bis-carboxy DBI PTCA;

FIG. 11 shows Raman spectrum of the ribtan layer;

FIG. 12 shows Raman spectra collected from the different points of ribtan layer surface;

FIG. 13 shows the resistivity measured parallel and perpendicular to coating direction as a function of maximum annealing temperature (Tₘₐₓ);

FIG. 14 shows the resistivity measured perpendicular to coating direction as a function of time of a sample exposure at maximum temperature;

FIG. 15 shows the voltage-current characteristics obtained at different annealing temperatures on bis-carboxy DBIPTCA layer;

FIGS. 16-20 schematically show a series of process steps of making patterned ribtan layer according to some embodiments of the present invention; and

FIG. 21 shows the chemical reactions taken place at a low-temperature carbonization process according to the present invention.

### DETAILED DESCRIPTION OF THE INVENTION

Various embodiments are described hereinafter with reference to the figures. It should be noted that the figures are not drawn to scale and elements of similar structures or functions are represented by like reference numerals throughout the figures. It should also be noted that the figures are only intended to facilitate the description of specific embodiments. They are not intended as an exhaustive description of the invention or as a limitation on the scope of the invention. In addition, an aspect described in conjunction with a particular embodiment is not necessarily limited to that embodiment and can be practiced in any other embodiments of the invention.

Hereinafter the name ribtan material is used for a new material disclosed. Ribtan is a carbon material which can exist in two modification: 1) it can consist of aligned graphene-like nanoribbons which are aligned parallel to each other and perpendicular (edge-on) to surface of substrate, and 2) it can consist of aligned graphene-like sheets which are aligned parallel to each other and parallel (face-on or homeotropic) to the surface of substrate. Graphene-like nanoribbons are narrow strips of graphene—one-atom-thick planar sheet of sp²-bonded carbon atoms that are densely packed in a honeycomb crystal lattice. Graphene-like sheets are wide sheets of graphene—one-atom-thick planar sheet of sp²-bonded carbon atoms that are densely packed in a honeycomb crystal lattice. The layers made of ribtan will be hereinafter named as ribtan layers. Technology of ribtan layers production will be hereinafter named ribtan technology. The ribtan technology is based on a thermally induced carbonization of organic compounds with predominantly planar carbon-conjugated cores.

Ribtan technology comprises a sequence of technological steps. The first step in ribtan technology is cascade crystallization process. Cascade crystallization is a method of the consecutive multi-step crystallization process for production of the solid precursor layers with ordered structure. The process involves a chemical modification step and several steps of ordering during the formation of the solid precursor layer. The chemical modification step introduces hydrophilic groups on the periphery of the molecule in order to impart amphiphilic properties to the molecule. Amphiphilic molecules stack together into supramolecules. The specific concentration is chosen, at which supramolecules are converted into a liquid-crystalline state to form a lyotropic liquid crystal (LLC), which is the next step of ordering. The LLC is deposited under the action of a shear force onto a substrate, so that the shear force direction determines the crystal axis direction in the resulting solid precursor layer. This shear-force—assisted directional deposition is the next step of ordering, representing the global ordering of the crystalline or polycrystalline structure on the substrate surface. The last step of the process is drying/crystallization, which converts the lyotropic liquid crystal into a solid precursor layer with highly ordered molecular structure. Planes of π-conjugated molecules in the formed precursor layer can be aligned parallel (face-on or homeotropic) or perpendicular (edge-on) to the surface of substrate depending on molecular structure and/or coating technique. Control over the precursor layer structure allows formation of layers comprising continuous graphene-like nanoribbons or graphene-like sheets with high electron mobility and low resistivity during carbonization process.

Cascade crystallization is followed by carbonization process named hereinafter as a step of formation of the metallic ribtan layer. Carbonization is the term for a set of conversion reaction of an organic substance into carbon. Carbonization is usually a heating cycle. Carbonization might be performed with a heater such as a radiating heater, resistive heater, heater using an ac-electric or magnetic field, heater using a flow of heated liquid, and heater using a flow of heated gas. Carbonization is performed in a reducing or inert atmosphere with a simultaneous slow heating, over a range of temperature that varies with the nature of the particular precursor and may extend to 2500° C. Carbonization is usually a complex process and several reactions may take place sequentially or simultaneously such as pyrolysis and fusion. Also carbonization process may be enhanced by addition of gas-phase or liquid-phase catalyst or reagents.

The first stage of carbonization is a pyrolysis process. Pyrolysis is the chemical decomposition of a condensed substance. Common products of pyrolysis are volatile compounds containing non-carbon atoms and solid carbon residue. Preferably the diffusion of the volatile compounds to the atmosphere occurs slowly to avoid disruption and rupture of the carbon network. As a result, carbonization is usually a slow process. Its duration may vary considerably depending on the composition of the end-product, type of precursor, thickness of the material, and other factors. Pyrolysis process converts the solid precursor layer into essentially all carbon (product of pyrolysis).

The second stage of carbonization is a fusion reaction. Fusion (in other words condensation or polymerization) in ribtan technology is chemical reactions between neighboring molecules or their pyrolized residues and which lead to growth of continuous graphene-like nanoribbons (in case of edge-on orientation of molecules in precursor layer) or stacked graphene-like sheets (in case of homeotropic precursor layer).

Several intermediate materials are formed during carbonization process. Product of pyrolysis consists of carbon cores separated by gaps. All structural parameters of the pyrolysis product (interplanar spacing; structure of residual carbon cores; dimensions of gaps between residual carbon cores and their concentration; orientation of carbon cores in respect to the substrate surface) are determined by structure of a precursor layer. Fusion process of product of pyrolysis leads to formation of an array of graphene-like nanoribbons or stacked graphene-like sheets with gaps. Generally, atomic structure of the nanoribbons or sheets with gaps is similar to the product of pyrolysis, but islands of sp² carbon atoms grow and get ribbon-like or sheet-like morphology. Structural parameters of the nanoribbons or sheets with gaps such as structure of residual carbon cores, dimensions of gaps between residual carbon cores and their concentration—are determined by parameters of carbonization process including but not limited to temperature, time, composition and pressure of ambient gas. Interplanar spacing and orientation of carbon cores in respect to the substrate surface depends on structure of precursor layer.

The intermediate materials described above have different electronic properties, especially conductivity. Mobility of charge carriers within graphene-like nanoribbon or graphene-like sheet reaches high values, which are approximately equal to 2*10⁵ cm²V⁻¹s⁻¹. Mobile charge carriers overcome the gaps between the graphene-like nanoribbons by hopping, and this conductivity is named hopping conductivity. Electrical properties of the intermediate material depend on the concentration of gaps in the graphene-like nanoribbons or graphene-like sheets. Larger concentration of gaps leads to a smaller total electrical conductivity of the layer. By controlling the concentration of gaps, the layers can be formed in any of three states: insulating, semiconducting and metallic. The semiconducting state and the metallic state can be characterized as electrical-conducting states. In the insulating state the material has resistivity in the range of 10⁸ Ω*cm to 10¹⁸ Ω*cm. In the semiconducting state, the resistivity of the material is in the range of 10⁻¹ Ω*cm to 10⁸ Ω*cm. In the metallic state, the resistivity of the material is in the range of 10⁻⁶ Ω*cm to 10⁻¹ Ω*cm. Thus, the mechanism of conductivity in the ribtan material differs from mechanisms of conductivity in semiconductors and metals. The term “semiconducting state” indicates that the conductivity value of ribtan material (in the range of 10⁻¹ Ω*cm to 10⁸ Ω*cm) is close to conductivity of semiconductor. The terms “metallic state” and “metallic ribtan layer” indicate that the conductivity value of ribtan material (in the range of 10⁻⁶ Ω*cm to 10⁻¹ Ω*cm) and ribtan layer is close to conductivity of metal.

There is no energy gap in the energy band structure of the graphene-like sheet. One possible method of creating an energy gap is the formation of thin graphene-like nanoribbons. The width of these graphene-like nanoribbons is selected so as to control the energy gap in electron energy distribution spectrum that is formed due to quantum-dimensional effects. Formation of the ordered graphene-like nanoribbons by fusion reaction in the ribtan structure allows precise control of a nanoribbon width simply by controlling the layer thickness. The precursor layer thickness depends only on solution concentration and coating parameters for layers obtained from LLC solution.

The ribtan technology allows the high volume production of ribtan layers over large surface (from several square millimeters to several square meters or larger). It allows low-cost manufacturing of the ribtan material for a broad range of different electronic devices, including integrated circuits.

In one embodiment of the disclosed integrated circuit, the interconnect system comprises an interconnector selected from the list comprising a direct interconnector, capacitive interconnector, and inductive interconnector.

In another embodiment of the disclosed integrated circuit, the circuit elements are formed at least on one surface of the substrate. In yet another embodiment of the disclosed integrated circuit, the circuit elements are formed on both surfaces of the substrate.

In still another embodiment of the disclosed integrated circuit, the substrate is made of one or several materials of the group comprising Si, Ge, SiGe, GaAs, diamond, quartz, silicon carbide, indium arsenide, indium phosphide, silicon germanium carbide, gallium arsenic phosphide, gallium indium phosphide, plastics, glasses, ceramics, metal-ceramic composites, metals, and comprises doped regions, circuit elements, and multilevel interconnects. In yet another embodiment of the disclosed integrated circuit, the plastic substrate is selected from the group comprising polycarbonate, Mylar, polyethylene terephthalate (PET) and polyimide.

In one embodiment of the disclosed integrated circuit, at least one circuit element is an active circuit element selected from the list comprising a transistor, diode, and monolithic device. In another embodiment of the disclosed integrated circuit, at least one circuit element is a passive circuit element selected from the list comprising an inductor, resistor, capacitor, radio frequency (Rf) antenna, magnetic coupling, transformer, plurality of input pads, and plurality of output pads.

In still another embodiment of the present invention, the integrated circuit involves functions selected from the list comprising electrical, optical, optoelectronic, and passive functions.

In one embodiment of the disclosed integrated circuit, the metallic ribtan material is prepared using at least one π-conjugated organic compound of a general structural formula I or a combination of the organic compounds of the general structural formula I:

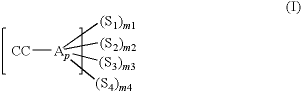

where CC is a predominantly planar carbon-conjugated core; A is a hetero-atomic group; p is 0, 1, 2, 3, 4, 5, 6, 7, or 8; S₁, S₂, S₃, and S₄ are substituents, at least one of which provides solubility of the organic compound in a solvent; m1, m2, m3 and m4 are 0, 1, 2, 3, 4, 5, 6, 7, or 8; and sum (m1+m2+m3+m4) is 1, 2, 3, 4, 5, 6, 7, 8, 9 or 10.

In another embodiment of the disclosed integrated circuit, the organic compound of the general formula I comprises one or more rylene fragments. Examples of such organic compound include structures 1-23 shown in Table 1.

TABLE 1
Examples of organic compounds with rylene fragments

| | |
|---|---|
| 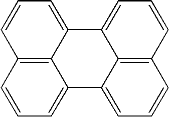 | 1 |
| 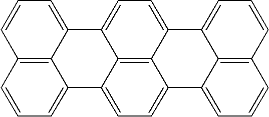 | 2 |
| 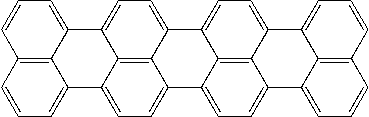 | 3 |
| 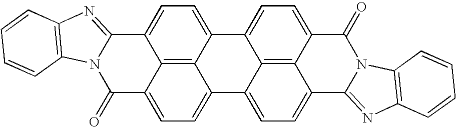 | 4 |
| 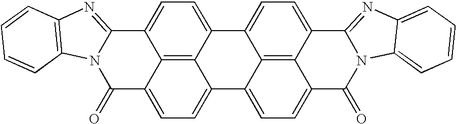 | 5 |
| 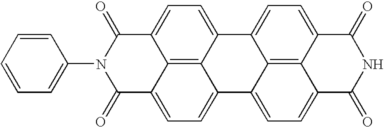 | 6 |
| 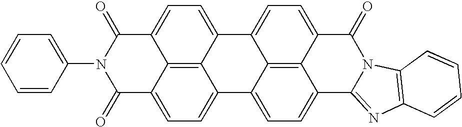 | 7 |
| 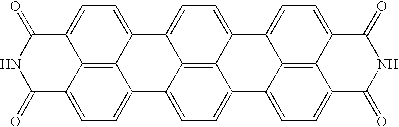 | 8 |
| 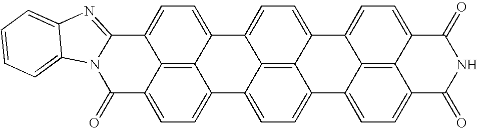 | 9 |
| 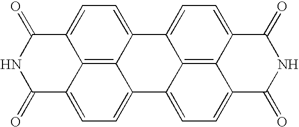 | 10 |
| 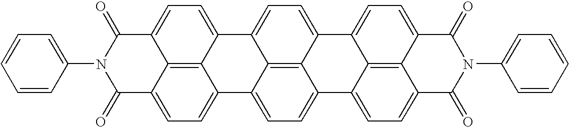 | 11 |
| 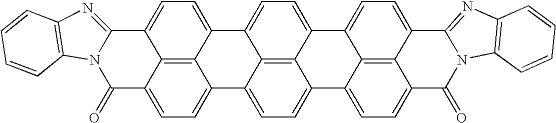 | 12 |
| 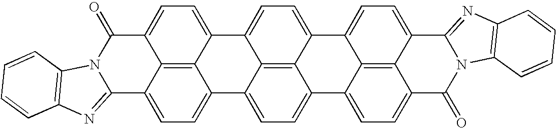 | 13 |
| 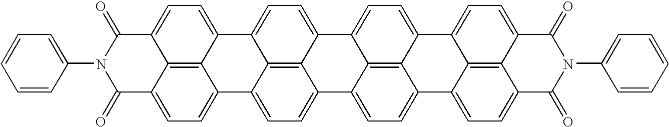 | 14 |
| 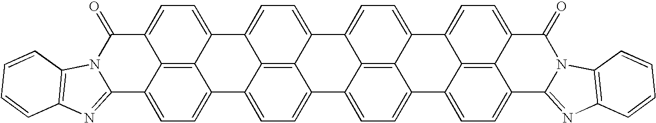 | 15 |
| 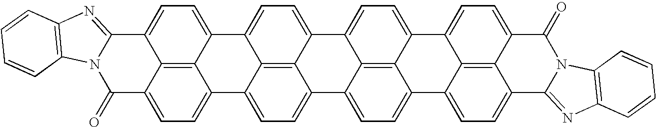 | 16 |
| 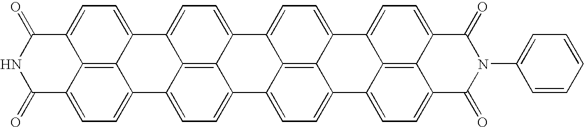 | 17 |
| 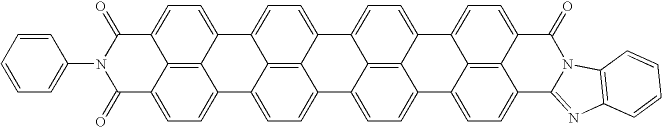 | 18 |
| 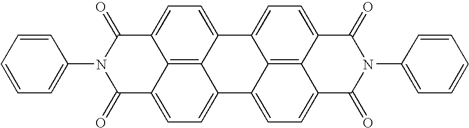 | 19 |
| 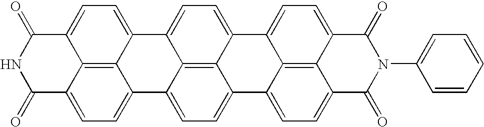 | 20 |
| 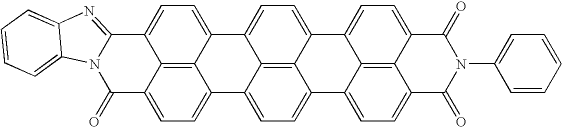 | 21 |
| 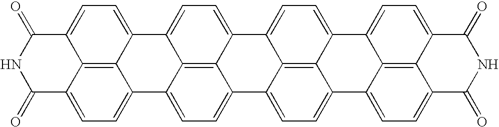 | 22 |
| 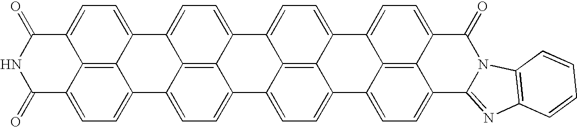 | 23 |

In still another embodiment of the disclosed integrated circuit, the organic compound of the general formula I comprises one or more anthrone fragments. Examples of such organic compounds include structures 24-31 shown in Table 2.

TABLE 2
Examples of organic compounds with anthrone fragments

| | |
|---|---|
| 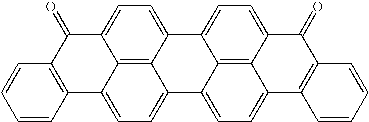 | 24 |
| 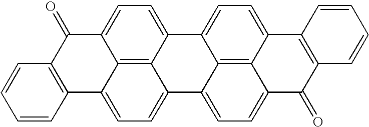 | 25 |
| 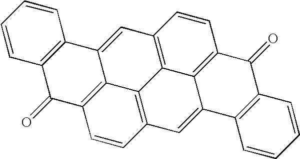 | 26 |
| 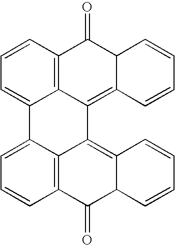 | 27 |
| 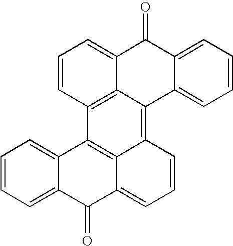 | 28 |
| 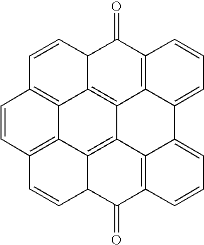 | 29 |
| 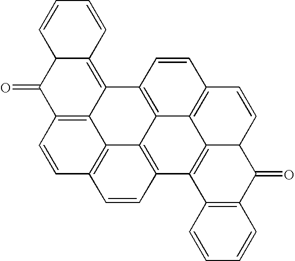 | 30 |
| 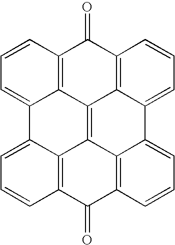 | 31 |

In yet another embodiment of the disclosed integrated circuit, the organic compound of the general formula I comprises fused polycyclic hydrocarbons. Examples of such organic compound include structures 32-43 shown in Table 3. The fused polycyclic hydrocarbons are selected from the list comprising truxene, decacyclene, antanthrene, hexabenzotriphenylene, 1,2,3,4,5,6,7,8-tetra-(peri-naphthylene)-anthracene, dibenzoctacene, tetrabenzoheptacene, peropyrene, hexabenzocoronene, violanthrene, isoviolanthrene.

TABLE 3
Examples of organic compounds with polycyclic hydrocarbons

| | |
|---|---|
| 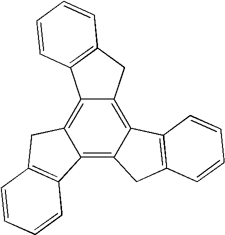 | 32 |
| 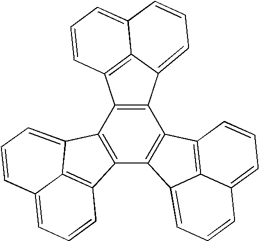 | 33 |
| 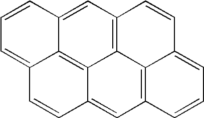 | 34 |
| 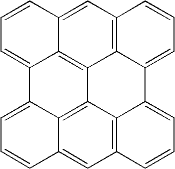 | 35 |
| 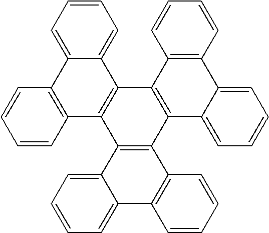 | 36 |
| 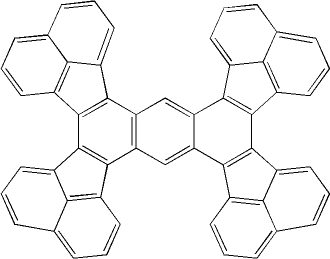 | 37 |
| 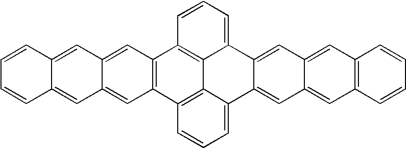 | 38 |
| 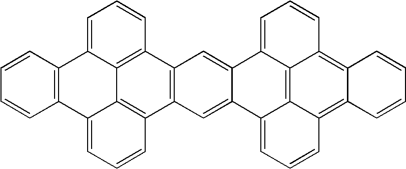 | 39 |
| 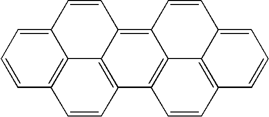 | 40 |
| 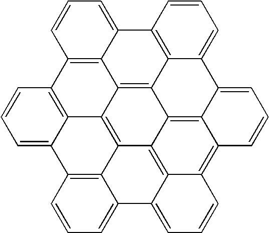 | 41 |
| 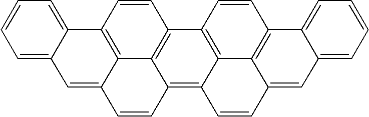 | 42 |
| 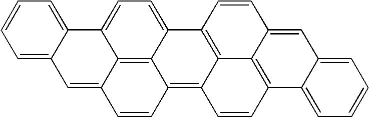 | 43 |

In one embodiment of the disclosed integrated circuit, the organic compound of the general formula I comprises one or more coronene fragments. Examples of such organic compounds include structures 44-51 shown in Table 4.

TABLE 4
Examples of organic compounds with coronene fragments

| | |
|---|---|
| 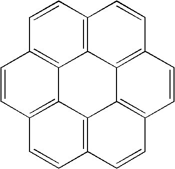 | 44 |
| 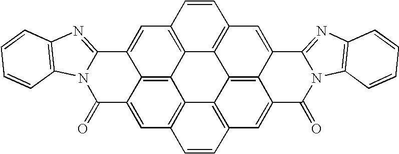 | 45 |
| 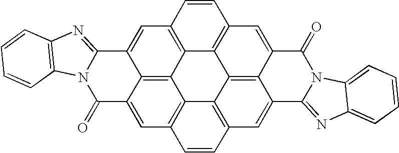 | 46 |
| 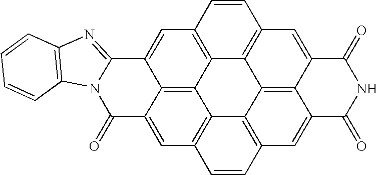 | 47 |
| 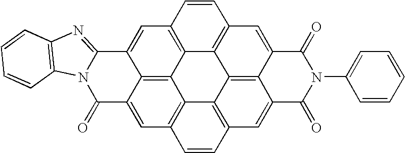 | 48 |
| 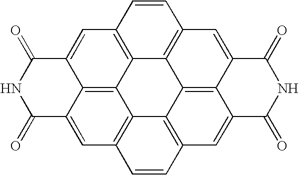 | 49 |
| 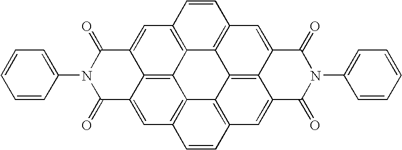 | 50 |
| 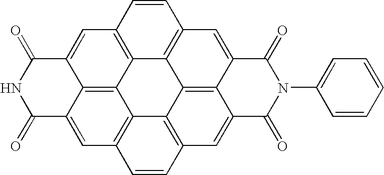 | 51 |

In yet another embodiment of the disclosed integrated circuit, the metallic ribtan material is prepared using a mixture of bis(carboxybenzimidazoles) of prerylenetetracarboxylic acids (bis-carboxy DBI PTCA).

In one embodiment of the disclosed integrated circuit, at least one of the hetero-atomic groups is selected from the list comprising imidazole group, benzimidazole group, amide group, substituted amide group, and hetero-atom selected from nitrogen, oxygen, and sulfur.

In another embodiment of the disclosed integrated circuit, at least one of the substituents S₁, S₂, S₃ and S₄ provides solubility of the organic compound in water or aqueous solution and is selected from the list comprising COO⁻, SO₃⁻, HPO₃⁻, and PO₃²⁻ and any combination thereof.

In still another embodiment of the disclosed integrated circuit, at least one of the substituents S₁, S₂, S₃ and S₄ provides solubility of the organic compound in the organic solvent and is selected from the list comprising CONR¹R², CONHCONH₂, SO₂NR¹R², R³, or any combination thereof, wherein R¹, R² and R³ are selected from hydrogen, an alkyl group, an aryl group, and any combination thereof, where the alkyl group has the general formula CₙH₂ₙ₊₁—where n is 1, 2, 3 or 4, and the aryl group is selected from the list comprising phenyl, benzyl and naphthyl. In yet another embodiment of the disclosed integrated circuit, at least one of the substituents S₁, S₂, S₃ and S₄ provides solubility of the organic compound in organic solvents and is selected from the list comprising (C₁-C₃₅)alkyl, (C₂-C₃₅)alkenyl, and (C₂-C₃₅)alkinyl. In one embodiment of the disclosed integrated circuit, at least one of the substituents S₁, S₂, S₃ and S₄ provides solubility of the organic compound in organic solvents and comprises fragments selected from the list comprising structures 52-58 shown in Table 5, where R is selected from the list, comprising linear or branched (C₁-C₃₅) alkyl, (C₂-C₃₅)alkenyl, and (C₂-C₃₅)alkinyl.

TABLE 5
Examples of fragments of the substituents providing solubility

| | |
|---|---|
| 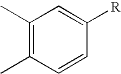 | 52 |
| 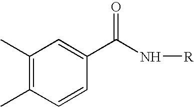 | 53 |
| 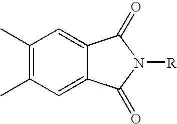 | 54 |
| 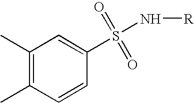 | 55 |
| 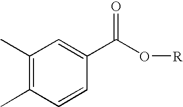 | 56 |
| 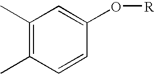 | 57 |
| 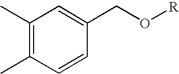 | 58 |

In yet another embodiment of the disclosed integrated circuit, the solution is based on the organic solvent. In one embodiment of the disclosed integrated circuit, the organic solvent is selected from the list comprising ketones, carboxylic acids, hydrocarbons, cyclohydrocarbons, chlorohydrocarbons, alcohols, ethers, esters, and any combination thereof. In another embodiment of the disclosed integrated circuit, the organic solvent is selected from the list comprising acetone, xylene, toluene, ethanol, methylcyclohexane, ethyl acetate, diethyl ether, octane, chloroform, methylenechloride, dichloroethane, trichloroethene, tetrachloroethene, carbon tetrachloride, 1,4-dioxane, tetrahydrofuran, pyridine, triethylamine, nitromethane, acetonitrile, dimethylformamide, dimethulsulfoxide, and any combination thereof.

In one embodiment of the disclosed integrated circuit, at least one of the substituents S₁, S₂, S₃ and S₄ is a molecular binding group which number and arrangement provide for the formation of planar supramolecules from the organic compound molecules in the solution via non-covalent chemical bonds. In another embodiment of the disclosed integrated circuit, at least one binding group is selected from the list comprising a hydrogen acceptor (A_{H}), hydrogen donor (D_{H}), and a group having a general structural formula

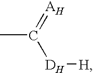

wherein the hydrogen acceptor (A_{H}) and hydrogen donor (D_{H}) are independently selected from the list comprising NH-group, and oxygen (O). In still another embodiment of the disclosed integrated circuit, at least one of the binding groups is selected from the list comprising hetero-atoms, COOH, SO₃H, H₂PO₃, NH, NH₂, CO, OH, NHR, NR, COOMe, CONH₂, CONHNH₂, SO₂NH₂, —SO₂—NH—SO₂—NH₂ and any combination thereof, where radical R is an alkyl group or an aryl group, the alkyl group having the general formula CₙH₂ₙ₊₁—where n is 1, 2, 3 or 4, and the aryl group being selected from the list comprising phenyl, benzyl and naphthyl. In one embodiment of the integrated circuit, at least one of the substituents S₁, S₂, S₃ and S₄ is selected from the list comprising —NO₂, —Cl, —Br, —F, —CF₃, —OCH₃, —OC₂H₅, —OCOCH₃, —OCN, —SCN, and —NHCOCH₃.

The present invention also provides a method for producing a metallic ribtan layer, as disclosed hereinabove. Disclosed method comprises the following steps: (a) application of a solution of at least one π-conjugated organic compound of a general structural formula I or a combination of the organic compounds of the general structural formula I on the substrate:

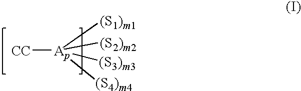

where CC is a predominantly planar carbon-conjugated core; A is a hetero-atomic group; p is 0, 1, 2, 3, 4, 5, 6, 7, or 8; S₁, S₂, S₃, and S₄ are substituents, m1, m2, m3 and m4 are 0, 1, 2, 3, 4, 5, 6, 7, or 8; and sum (m1+m2+m3+m4) is 1, 2, 3, 4, 5, 6, 7, 8, 9 or 10, (b) drying with formation of a solid precursor layer, and (c) formation of the metallic ribtan layer. Said formation step is characterized by a level of vacuum, a composition and pressure of ambient gas, and a time dependence of temperature which are selected so as to ensure a creation of predominantly planar graphene-like structures in the metallic ribtan layer. At least one said graphene-like structure possesses conductivity and is predominantly continuous within the entire metallic ribtan layer. The thickness of the metallic ribtan layer is in the range from approximately 1 nm to 1000 nm.

In one embodiment of the disclosed method, the predominantly planar carbon-conjugated core (CC), the substituents S₁, S₂, S₃, and S₄, and coating conditions are selected so that the graphene-like structures have a form of planar graphene-like nanoribbons, the planes of which are oriented predominantly perpendicularly to the substrate surface. In another embodiment of the disclosed method, the predominantly planar carbon-conjugated core (CC), the substituents S₁, S₂, S₃, and S₄, and coating conditions are selected so that the graphene-like structures have a form of planar graphene-like sheets the planes of which are oriented predominantly parallel to the substrate surface. In yet another embodiment of the disclosed method, the drying and formation steps are carried out simultaneously or sequentially. In still another embodiment of the disclosed method, the ambient gas comprises chemical elements selected from the list comprising hydrogen, nitrogen, fluorine, arsenic, boron, carbon tetrachloride, halogens, halogenated hydrocarbons, and any combination thereof.

In one embodiment of the present invention, the disclosed method further comprises a post-treatment in a gas atmosphere. The post-treatment step is carried out after the formation step, and the gas atmosphere comprises chemical elements selected from the list comprising hydrogen, nitrogen, fluorine, arsenic, boron, carbon tetrachloride, halogens, halogenated hydrocarbons, and any combination thereof.

In another embodiment of present invention, the disclosed method further comprises a doping step carried out after the formation step and/or after the post-treatment step and during which the metallic ribtan layer is doped with impurities. The doping step is based on a method selected from the list comprising diffusion method, intercalation method and ion implantation method, and the impurity is selected from the list comprising Sb, P, As, Ti, Pt, Au, O, B, Al, Ga, In, Pd, S, F, N, Br, I and any combination thereof. In one embodiment of the disclosed method, at least one of the hetero-atomic groups is selected from the list comprising imidazole group, benzimidazole group, amide group and substituted amide group.

In another embodiment of the disclosed method, said solution is based on water and at least one of the substituents providing solubility of the organic compound is selected from the list comprising COO⁻, SO₃⁻, HPO₃⁻, and PO₃²⁻, and any combination thereof.

In yet another embodiment of the disclosed method, said solution is based on an organic solvent and the organic solvent is selected from the list comprising ketones, carboxylic acids, hydrocarbons, cyclohydrocarbons, chlorohydrocarbons, alcohols, ethers, esters, acetone, xylene, toluene, ethanol, methylcyclohexane, ethyl acetate, diethyl ether, octane, chloroform, methylenechloride, dichloroethane, trichloroethene, tetrachloroethene, carbon tetrachloride, 1,4-dioxane, tetrahydrofuran, pyridine, triethylamine, nitromethane, acetonitrile, dimethylformamide, dimethulsulfoxide, and any combination thereof. At least one of the substituents providing solubility of the organic compound in the organic solvent is selected from the list comprising linear and branched (C₁-C₃₅)alkyl, (C₂-C₃₅)alkenyl, and (C₂-C₃₅)alkinyl, an amide of an acid residue independently selected from the list comprising CONR₁R₂, CONHCONH₂, SO₂NR₁R₂, R₃, and any combination thereof. The radicals R₁, R₂ and R₃ are independently selected from the list comprising a hydrogen, linear alkyl group, branched alkyl group, aryl group, and any combination thereof. The alkyl group has a general formula —(CH₂)ₙCH₃, where n is an integer from 0 to 27, and the aryl group is selected from the group comprising phenyl, benzyl and naphthyl. In yet another embodiment of the disclosed method, the organic compound further comprises at least one bridging group B_{G} to provide a connection between at least one of the substituents providing solubility of the organic compound in the organic solvent and the predominantly planar carbon-conjugated core and wherein at least one of the bridging groups B_{G} is selected from the list, comprising —C(O)—, —C(O)O—, —C(O)—NH—, —(SO₂)NH—, —O—, —CH2O—, —NH—, >N—, and any combination thereof.

In one embodiment of the disclosed method, said organic compound comprises rylene fragments having a general structural formula from the group comprising structures 1-23 shown in Table 1. In another embodiment of the disclosed method, said organic compound comprises anthrone fragments having a general structural formula from the group comprising structures 24-31 shown in Table 2. In yet another embodiment of the disclosed method, said organic compound comprises fused polycyclic hydrocarbons selected from the list comprising truxene, decacyclene, antanthrene, hexabenzotriphenylene, 1,2,3,4,5,6,7,8-tetra-(peri-naphthylene)-anthracene, dibenzoctacene, tetrabenzoheptacene, peropyrene, hexabenzocoronene, violanthrene, isoviolanthrene and having a general structural formula from the group comprising structures 32-43 shown in Table 3. In still another embodiment of the disclosed method, said organic compound comprises coronene fragments having a general structural formula from the group comprising structures 44-51 shown in Table 4.

In one embodiment of the disclosed method, said drying stage is carried out using an airflow. In another embodiment of the present invention, the disclosed method further comprises the pre-treatment of the substrate prior to the application of said solution so as to render its surface hydrophilic.

In yet another embodiment of the disclosed method, a type of said solution is selected from the list comprising an isotropic solution and a lyotropic liquid crystal solution.

In still another embodiment of present invention, the disclosed method further comprises an alignment action, wherein the alignment action is simultaneous or subsequent to the application of said solution on the substrate. In one embodiment of the disclosed method, said application stage is carried out using a technique selected from the list comprising a spray-coating, Mayer rod technique, blade coating, extrusion, roll-coating, curtain coating, knife coating, slot-die application and printing.

In another embodiment of the disclosed method, the π-conjugated organic compound further comprise molecular binding groups which number and arrangement thereof provide for the formation of planar supramolecules from the organic compound molecules in the solution via non-covalent chemical bonds. At least one said binding group is selected from the list comprising hetero-atoms, COOH, SO₃H, H₂PO₃, NH, NH₂, CO, OH, NHR, NR, COOMe, CONH₂, CONHNH₂, SO₂NH₂, —SO₂—NH—SO₂—NH₂, and any combination thereof, a hydrogen acceptor (A_{H}), hydrogen donor (D_{H}), and group having a general structural formula

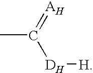

The radical R is independently selected from the list comprising a linear alkyl group, branched alkyl group, aryl group, and any combination thereof, where the alkyl group has a general formula —(CH₂)ₙCH₃, where n is an integer from 0 to 27, and where the aryl group is selected from the group comprising phenyl, benzyl and naphthyl. The hydrogen acceptor (A_{H}) and hydrogen donor (D_{H}) are independently selected from the list comprising NH-group, and oxygen (O). The non-covalent chemical bonds are independently selected from the list comprising a single hydrogen bond, dipole-dipole interaction, cation—pi-interaction, Van-der-Waals interaction, coordination bond, ionic bond, ion-dipole interaction, multiple hydrogen bond, interaction via the hetero-atoms, and any combination thereof, and the planar supramolecule have the form selected from the list comprising disk, plate, lamella, nanoribbon, and any combination thereof.

In another embodiment of the disclosed method, the rod-like supramolecules are predominantly oriented in the plane of the substrate. In yet another embodiment of the disclosed method, the formation step is carried out in vacuum or inert gas.

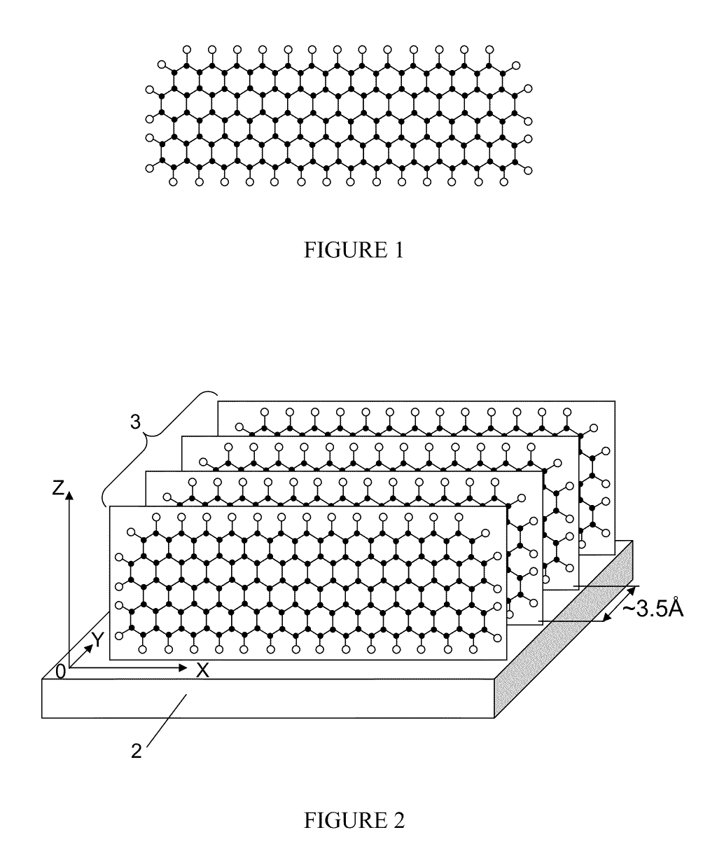

In still another embodiment of the disclosed method, the formation step is carried out so as to ensure 1) partial pyrolysis of the organic compound with at least partial removing of substituents, hetero-atomic and solubility groups from the solid precursor layer, and 2) fusion of the carbon-conjugated residues. The formation step results in the creation of predominantly planar graphene-like carbon-based structures via fusion of the carbon-conjugated residues under high temperatures. One possible embodiment of such graphene-like carbon-based structures is shown schematically in FIG. 1. The graphene-like structure comprises a substantially planar hexagonal carbon core (the carbon atoms are marked as black circles in FIG. 1). The hexagonal carbon core possesses high electrical conductivity which is close to conductivity of metal. Atoms of hydrogen (white circles in FIG. 1) are positioned along the perimeter of the graphene-like carbon-based structure. FIG. 2 schematically shows the anisotropic ribtan layer (3) on the substrate (2) after the formation step.

Resistivity of the metallic ribtan material is in the range of 10⁻¹ Ωcm to 10⁻⁶ Ωcm. The ribtan material possesses anisotropy of resistivity, e.g., the resistivity along graphene-like nanoribbons (Rₚₑᵣ) is lower than the resistivity across the nanoribbons (Rₚₐᵣ). Generally, resistivity decreases with increasing of exposure time and fusion temperature. Such anisotropy of resistivity corresponds to a better charge transport in the direction along the graphene-like carbon-based structures.

In one embodiment of the disclosed method, the pyrolysis temperature is in the range between approximately 150 and 650 degrees C., and the fusion temperature is in the range between approximately 500 and 2500 degrees C. In another embodiment of the disclosed method, the formation step is carried out without heating or under moderate heating (less than approximately 500 degrees C.) under the action of gas-phase or liquid phase environment containing molecules which are sources of free radicals or benzyne fragments. In yet another embodiment of the disclosed method, said formation step is further accompanied by applying an external action upon the metallic ribtan layer stimulating low-temperature carbonization process and formation of the graphene-like carbon-based structures.

In one embodiment of the present invention, the disclosed method further comprises the step of removing the substrate by one of the methods selected from the list comprising wet chemical etching, dry chemical etching, plasma etching, laser etching, grinding, and any combination thereof.

In yet another embodiment of the disclosed method, number of the substituents S1, S2, S3, and S4 providing solubility of the organic compound is equal or more than 2 and the substituents are the same or at least one said substituent is different from other or others.

In still another embodiment of the disclosed method, the steps (a), (b) and (c) are consecutively repeated two or more times, and sequential metallic ribtan layers are formed using solutions based on the same or different organic compounds or their combinations. In one embodiment of the disclosed method, at least one said π-conjugated organic compound further comprises substituents independently selected from a list comprising —NO₂, —Cl, —Br, —F, —CF₃, —CN, —OH, —OCH₃, —OC₂H₅, —OCOCH₃, —OCN, —SCN, —NH₂, —NHCOCH₃, and —CONH₂.

The present invention also provides a method for producing a metallic ribtan layer, as disclosed hereinabove. Disclosed method comprises the following steps: (a) preparation of a solution of one π-conjugated organic compound of a general structural formula II or a combination of the organic compounds of the general structural formula II capable of forming supramolecules:

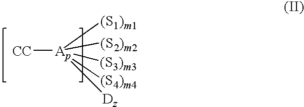

where CC is a predominantly planar carbon-conjugated core; A is an hetero-atomic group; p is 0, 1, 2, 3, 4, 5, 6, 7, or 8; S₁, S₂, S₃, S₄ and D are substituents, where S₁, S₂, S₃, and S₄ are substituents providing solubility of the organic compound in a suitable solvent, and D is a substituent which produces reaction centers selected from the list comprising free radicals and benzyne fragments on the predominantly planar carbon-conjugated cores after a subsequent elimination of this substituent during a step (e) of the disclosed method; m1, m2, m3 and m4 are 0, 1, 2, 3, 4, 5, 6, 7, or 8; sum (m1+m2+m3+m4) is 1, 2, 3, 4, 5, 6, 7, 8, 9 or 10, and z is 0, 1, 2, 3 or 4; (b) deposition of a layer of the solution on the substrate; (c) an alignment action upon the solution in order to ensure a preferred alignment of the supramolecules; (d) drying with formation of a solid precursor layer; and (e) application of an external action upon the solid layer stimulating low-temperature carbonization and formation of the graphene-like carbon-based structures.

In one embodiment of the disclosed method, the substituent D is selected from the list comprising halogens Cl, Br and I. In another embodiment of the disclosed method, said deposition step is carried out using a technique selected from the list comprising a spray-coating, Mayer rod technique, blade coating, slot-die application, extrusion, roll coating, curtain coating, knife coating, and printing.

In yet another embodiment of the alignment action is produced by a directed mechanical motion of at least one aligning instrument selected from the list comprising a knife, cylindrical wiper, flat plate and any other instrument oriented parallel to the deposited solution layer surface, whereby a distance from the substrate surface to the edge of the aligning instrument is preset so as to obtain a solid precursor layer of a required thickness. In still another embodiment of the disclosed method, the alignment action is performed by using a technique selected from the list comprising a heated instrument, application of an external electric field to the deposited solution layer, application of an external magnetic field to the deposited solution layer, application of an external electric and magnetic field to the deposited solution layer, with simultaneous heating, illuminating the deposited solution layer with at least one coherent laser beams, and any combination of the above listed techniques.

In one embodiment of the disclosed method, the external action is selected from the list comprising a thermal treatment and ultraviolet irradiation. In another embodiment of the disclosed method, the thermal treatment is carried out at the temperature not exceeding the melting temperature of the substrate material.

In yet another embodiment of the disclosed method, said organic compound comprises rylene fragments having a general structural formula from the group comprising structures 1-23 shown in Table 1. In still another embodiment of the disclosed method, said organic compound comprises anthrone fragments having a general structural formula from the group comprising structures 24-31 shown in Table 2. In one embodiment of the disclosed method, said organic compound comprises fused polycyclic hydrocarbons selected from the list comprising truxene, decacyclene, antanthrene, hexabenzotriphenylene, 1,2,3,4,5,6,7,8-tetra-(peri-naphthylene)-anthracene, dibenzoctacene, tetrabenzoheptacene, peropyrene, hexabenzocoronene, violanthrene and isoviolanthrene and having a general structural formula from the group comprising structures 32-43 shown in Table 3. In another embodiment of the disclosed method, said organic compound comprises coronene fragments having a general structural formula from the group comprising structures 44-51 shown in Table 4. In yet another embodiment of the present invention, the disclosed method further comprises a step of placement of the solid layer into a gas-phase environment containing molecules which are sources of free radicals or benzyne fragments, wherein this additional step is carried out after the drying step.

The present invention will now be described more fully hereinafter with reference to the following example, in which preferred embodiments of the present invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity.

### EXAMPLES

### Example 1

The example describes synthesis of bis(carboxybenzimidazoles) of perylene tetracarboxylic acid (rylene fragments ##4 and 5 in Table 1):

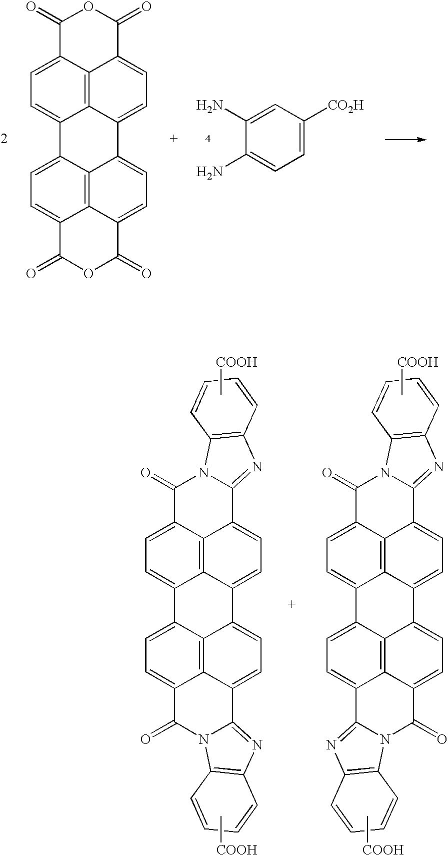

Mixture of 3,4,9,10-perylenetetracarboxylic-3,4:9,10-dianhydride (10 g) and 3,4-diaminobenzoic acid (39 g) was agitated in N-methylpyrrolidone (250 ml) for 6 hours at 175-180° C. A self cooled reaction mass was filtered. Filter cake was rinsed with N-methylpyrrolidone and dissolved in a mixture of water (1500 ml) and concentrated ammonia solution (100 ml). Dimethylformaide (1 L) was added to the solution. Precipitate was filtered and rinsed with dimethylformaide. Filter cake was suspended in water (1 L). Concentrated hydrochloric acid (100 ml) was added and the precipitate was filtered. Obtained filter cake was suspended in ˜500 ml of water, filtered and rinsed with water. Yield 13.2 g.

### Example 2

The example describes synthesis of diphenylimide of 3,4,9,10-perylenetetracarboxylic acid (rylene fragment #19 in Table 1):

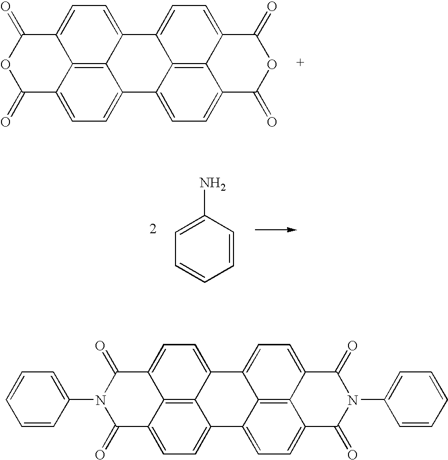

Mixture of 3,4,9,10-perylenetetracarboxylic-3,4:9,10-dianhydride (40 g), aniline (38 ml), zinc chloride (21 g) and ethylene glycol (400 ml) was agitated 8 hours at 180-185° C. After self cooling process a precipitate was filtered and rinsed with hot water (1 L). Filter cake was agitated in 1% solution of potassium hydroxide for 2 hours. Precipitate was filtered and rinsed with hot water (1 L). Filter cake was agitated in a 2% solution of hydrogen chloride for 1 hour at 90° C. Precipitate was filtered and rinsed with hot water (1 L). Filter cake was agitated in 1% solution of potassium hydroxide for 2 hours. Precipitate was filtered and rinsed with hot water (1 L). Filter cake was agitated in a 2% solution of hydrogen chloride for 1 hour at 90° C. Precipitate was filtered and rinsed with hot water (1 L) and dried at 100° C. Yield 38.3 g.

### Example 3

The example describes synthesis of dicarboxymethylimide of perylentetracarboxylic acid (carboxylic acid of base rylene fragment 10 in the Table 1)

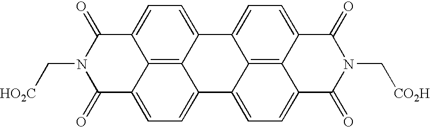

Mixture of 3,4,9,10-perylenetetracarboxylic-3,4:9,10-dianhydride (2 g) and glycine (3.8 g) was agitated in the boiling N-methylpyrrolidone (50 ml) for 6 hours. A self cooled reaction mass was filtered. Filter cake was rinsed with N-methylpyrrolidone, hydrochloric acid and water. Obtained filter cake was suspended in ˜300 ml of water, filtered and rinsed with water. Yield 0.73 g.

### Example 4

The example describes synthesis of violanthrone disulfonic acid (anthrone fragment #24 in Table 2):

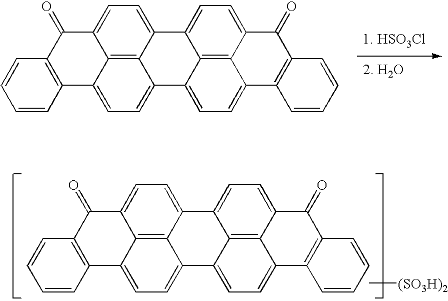

Violanthrone (10 g) was added to chlorosulfonic acid (50 ml) at ambient conditions. Then reaction mass was agitated at 85-90° C. for 15 hours. After self cooling a reaction mass was added by parts into water (600 ml). Precipitate was filtered and rinsed with water until filtrate became colored. Filter cake was agitated in the boiling water (500 ml) for two hours. The product was precipitated by addition of concentrated hydrochloric acid (600 ml). Precipitate was filtered, washed with 6 N hydrochloric acid (200 ml) and dried in oven (˜100° C.). Yield 11.8 g.

### Example 5

The example describes synthesis of isoiolanthrone disulfonic acid (anthrone fragment #25 in Table 2):

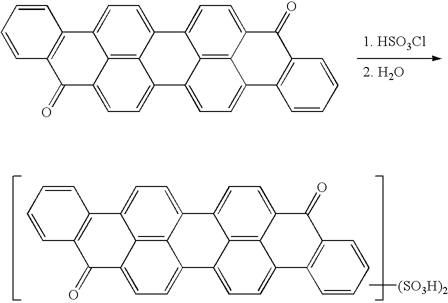

Isoviolanthrone (10 g) was charged into chlorosulfonic acid (50 ml) at ambient conditions. Then reaction mass was agitated at 85-90° C. for 16 hours. After self cooling a reaction mass was added into water (600 ml) by portions. Filter cake was agitated in the boiling water (600 ml) for 3 hours. The obtained hot solution was filtered through fiber glass filters. The substance was precipitated by addition of concentrated hydrochloric acid (550 ml). Precipitate was filtered, washed with 4 N hydrochloric acid (200 ml). Filter cake was suspended in 300 ml of 4 N hydrochloric acid. Precipitate was filtered, washed with 4 N hydrochloric acid (100 ml) and dried in oven (˜100° C.). Yield 7.5 g.

### Example 6

The example describes synthesis of decacyclene (polycyclic hydrocarbon fragment #33 in Table 3):

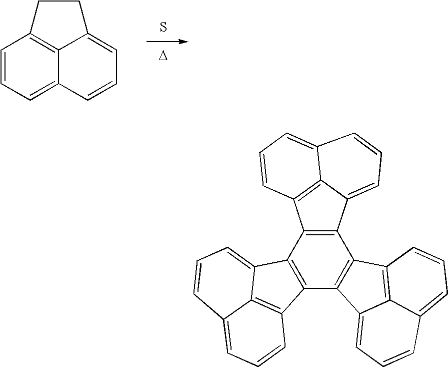

Mixture of sulfur powder (10 g), acenaphthene (31 g) and potassium hydroxide (0.4 g) was heated at 230-300° C. for 7 hours. Obtained fusion cake was ground and agitated in a boiling tetrachloroethane (200 ml) for 4 hours. Suspension was filtered at ˜80° C. Filter cake was agitated in a boiling tetrachloroethane (200 ml) for 2 hours. Cooled suspension was filtered. Filter cake was rinsed with tetrachloroethane and suspended in a hot N-methylpyrrolidone (300 ml, ˜150° C.). Cooled suspension was diluted with isopropanol (400 ml) and a precipitate was filtered. Filter cake was suspended in hot N-methylpyrrolidone (400 ml, ˜150° C.). Cooled suspension was filtered. Filtrate was diluted with water (1.5 L). Obtained precipitate was filtered, rinsed with water and dried at ˜100° C. 11.2 g of dry powder were prepared.

Filtrate (N-methylpyrrolidone-isopropanol) was diluted with water (1 L). Precipitate was filtered, rinsed with water and dried at ˜100° C. 1.18 g of dry powder was prepared. Obtained powder was combined and agitated in a boiling tetrachloroethane (70 ml) for 2 hours. Cooled suspension was filtered. Filter cake was rinsed with tetrachloroethane and chloroform. Obtained powder (10.8 g) was suspended in hot N-methylpyrrolidone (400 ml, ˜150° C.). Cooled suspension was diluted with water (1 L). Obtained precipitate was filtered, rinsed with water and dried at ˜100° C. Yield 6.5 g.

### Example 7

The example describes synthesis of decacyclene trisulfonic acid (polycyclic hydrocarbon fragment #33 in Table 3):

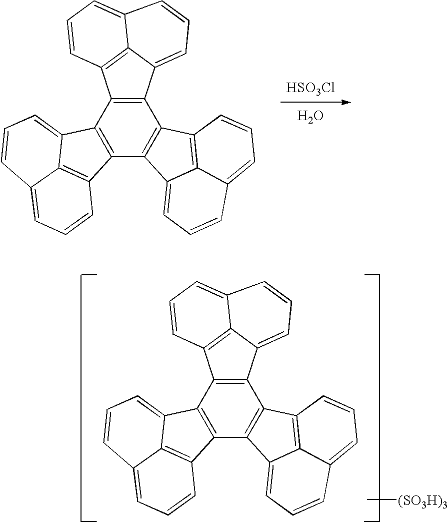

Decacyclene (1 g) was charged into chlorosulfonic acid (5 ml) at ambient conditions. During charging hydrogen chloride was liberating. Then reaction mass was agitated at the room temperature for 48 hours. Then reaction mass was added into water (50 ml) by portions. Precipitate was filtered. Filter cake was agitated in water (100 ml) at ambient conditions and in hot water (80° C.) for 2 hours. Prepared solution was filtered through fiber glass filter. Filtrate was diluted with concentrated hydrochloric acid (100 ml) and dried at ˜100° C. Yield 1.13 g.

### Example 8

The example describes synthesis of truxene (polycyclic hydrocarbon fragment #32 in Table 3):

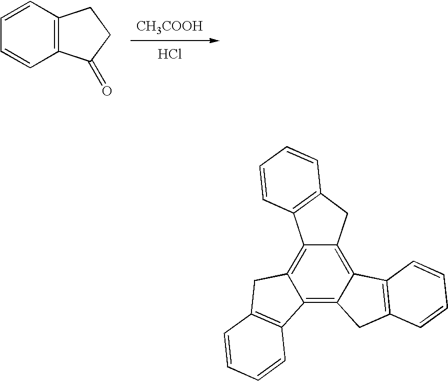

1-Indanone (5.0 g) was inserted into a mixture of acetic acid (22 mL) and concentrated hydrochloric acid (11 mL). The resultant solution was agitated at 95-97° C. for 16 hours. Color turned yellow, bulky precipitate formed. The precipitate was filtered off, the solid material was washed with water (2×100 mL) and with acetone (100 mL, cold 5-7° C.). Yield 3.2 g.

### Example 9

The example describes synthesis of truxene trisulfonic acid (polycyclic hydrocarbon fragment #32 in Table 3):

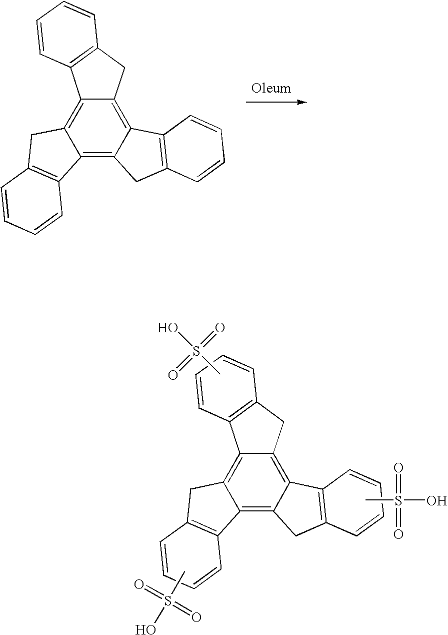

Truxene (3.4 g) was charged into oleum (80 mL, 4%), slowly for 15 min trying to keep particles of the substance as fine as possible. The outer water bath was used to insure the room temperature of reaction mixture. Reaction mass was agitated for 5 hours. After that it was added dropwise into ice (135 g). Pale-crème precipitate was diluted with concentrated hydrochloric acid (150 mL), stirred overnight, filtered off, then washed with concentrated hydrochloric acid (150 mL), water (60 mL), and the resultant solution was diluted with 36% hydrochloric acid (150 mL). A jelly brown-green jelly precipitate was formed, solution was removed, and a fresh portion of hydrochloric acid was added (150 mL). Stirring was continued whereas a jelly mass turned to a solid precipitate. Then suspension was filtered, the solid material was washed with concentrated hydrochloric acid (50 mL), dried over wet sodium hydroxide, phosphorous oxide with mild heating. Yield 6.7 g.

### Example 10

Example describes preparation of N,N′-(1-undecyl)dodecyl-5,11-dihexylcoronene-2,3:8,9-tetracarboxydiimide (coronene fragment 49 in the Table 4). The preparation comprised 6 steps:

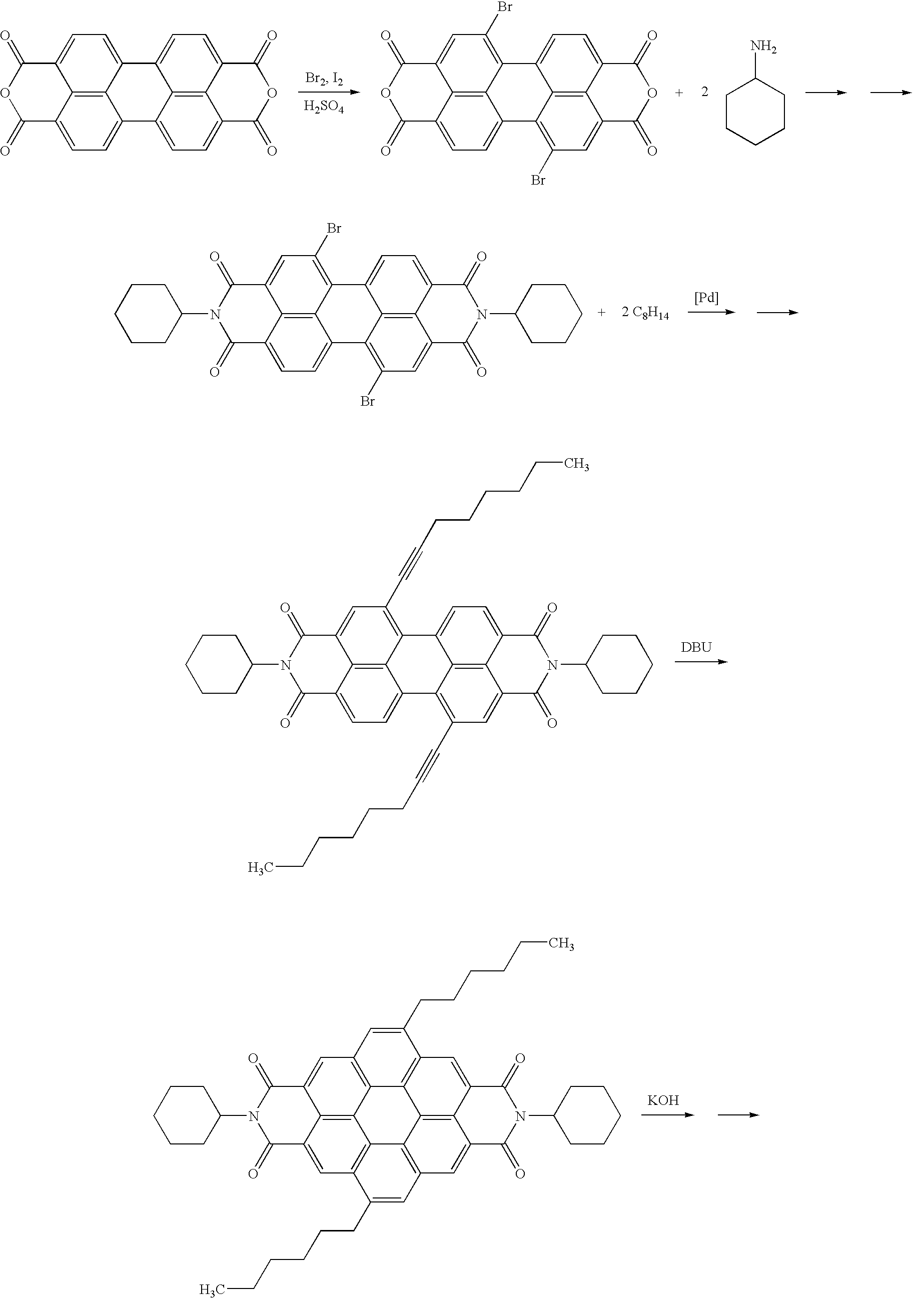

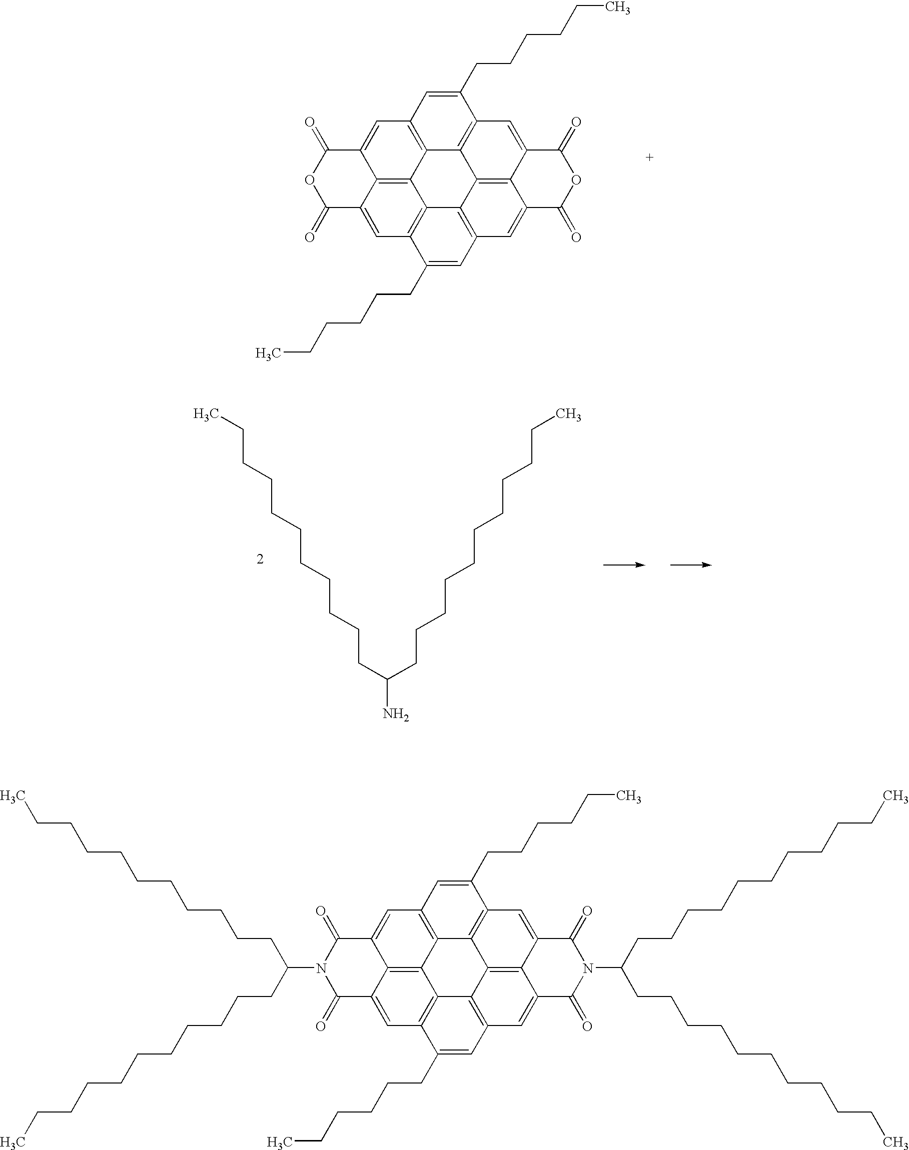

Commercially available perylene-3,4:9,10-tetracarboxylic dianhydride (100.0 g, 0.255 mol) was brominated with mixture of bromine (29 mL) and iodine (2.38 g) in 100% sulfuric acid (845 mL) at. ˜85° C. The yield of 1,7-Dibromoperylene-3,4:9,10-tetracarboxylic dianhydride was 90 g (64%).

Analysis: calculated: C₂₄H₆Br₂O₆, C, 52.40; H, 1.10; Br, 29.05; O, 17.45%. found: C, 52.29; H, 1.07; Br, 28, 79%. Absorption spectrum (9.82×10⁻⁵ M solution in 93% sulfuric acid): 405 (9572), 516 (27892), 553 (37769).

N,N′-Dicyclohexyl-1,7-dibromoperylene-3,4:9,10-tetracarboxydiimide was synthesized by the reaction of 1,7-dibromoperylene-3,4:9,10-tetracarboxylic dianhydride (30.0 g) with cyclohexylamine (18.6 mL) in N-methylpyrrolidone (390 mL) at ˜85° C.

The yield of N,N′-dicyclohexyl-1,7-dibromoperylene-3,4:9,10-tetracarboxydiimide was 30 g (77%).

N,N′-dicyclohexyl-1,7-di(oct-1-ynyl)perylene-3,4:9,10-tetracarboxydiimide was synthesized by Sonagashira reaction: N,N′-dicyclohexyl-1,7-dibromperylene-3,4:9,10-tetracarboxydiimide (24.7 g) and octyne-1 (15.2 g) in the presence of bis(triphenylphosphine)palladium(II) chloride (2.42 g), triphenylphospine (0.9 g), and copper(I) iodide (0.66 g). The yield of N,N′-dicyclohexyl-1,7-di(oct-1-ynyl)perylene-3,4:9,10-tetracarboxydiimide was 15.7 g (60%).

N,N′-dicyclohexyl-5,11-dihexylcoronene-2,3:8,9-tetracarboxydiimide was synthesized by the heating of N,N′-dicyclohexyl-1,7-di(oct-1-ynyl)perylene-3,4:9,10-tetracarboxydiimide (7.7 g) in toluene (400 mL) in the presence of 1,8-diazabicyclo[5.4.0]undec-7-ene (0.6 ml) at 100-110° C. for 20 hours.

5,11-dihexylcoronene-2,3:8,9-tetracarboxylic dianhydride was prepared by hydrolysis of N,N′-dicyclohexyl-5,11-dihexylcoronene-2,3:8,9-tetracarboxydiimide (6.4 g, 8.3 mmol) with potassium hydroxide (7.0 g, 85%) in the mixture of tert-butanol (400 mL) and water (0.4 mL) at 85-90° C. The yield of 5,11-dihexylcoronene-2,3:8,9-tetracarboxylic dianhydride was 4.2 g (83%).

N,N′-(1-undecyl)dodecyl-5,11-dihexylcoronene-2,3:8,9-tetracarboxydiimide was synthesized by the reaction of 5,11-di(hexyl)coronene-2,3:8,9-tetracarboxylic dianhydride with 12-tricosanamine.

5,11-di(hexyl)coronene-2,3:8,9-tetracarboxylic dianhydride (3.44 g), 12-tricosanamine (7.38 g), benzoic acid (45 mg) and 3-Chlorophenol (15 mL) were evacuated and saturated with argon two times at room temperature and then two times at 100° C. The reaction mixture was agitated at ˜140° C. for 1 hour and 160-165° C. for 20 hours in a flow of argon. After that the reaction mixture was agitated at ˜100° C. and was vacuumed at 10 mm Hg for half an hour. Then apparatus was filled with argon once again and heating was continued for the next 24 hours. A drop of reaction mixture was mixed with acetic acid (5 mL), centrifuged, solid was dissolved in chloroform (0.5 mL) which was washed with water and dried over sodium sulfate. Thin layer chromatography probe showed good formation of product with Rf 0.9 (eluent: chloroform-hexane-ethylacetate-methanol (100:50:0.3:0.1 by V)).

The reaction mixture was added in small portions to acetic acid (500 mL) with simultaneous shaking. The orange-red suspension was kept for 3 hours with periodic shaking, then filtered off. The filter cake was washed with water (0.5 L), and then was shaken with water (0.5 L) and chloroform (250 mL) in a separator funnel. The organic layer was separated, washed with water (2×350 mL) and dried over sodium sulfate overnight. The evaporation resulted in 7.0 g of crude product.

Column chromatography was carried out using exactly tuned eluent mixture: chloroform (700 mL), petroleum ether (2 L), ethylacetate (0.6 mL) and methanol (0.2). Column chromatography was carried out using column: l=20, d=7 cm. Elution of orange fraction and evaporation resulted in orange soft solid material, which was dissolved in chloroform (25 mL) and added slowly to methanol (400 mL) with agitation. The soft precipitate was dried on air overnight, then in vacuum (15 mm Hg) at mild heating (35°) for 5 hours. The yield of preparation of N,N′-(1-undecyl)dodecyl-5,11-dihexylcoronene-2,3:8,9-tetracarboxydiimide was 5.0 g (70%).

### Example 11

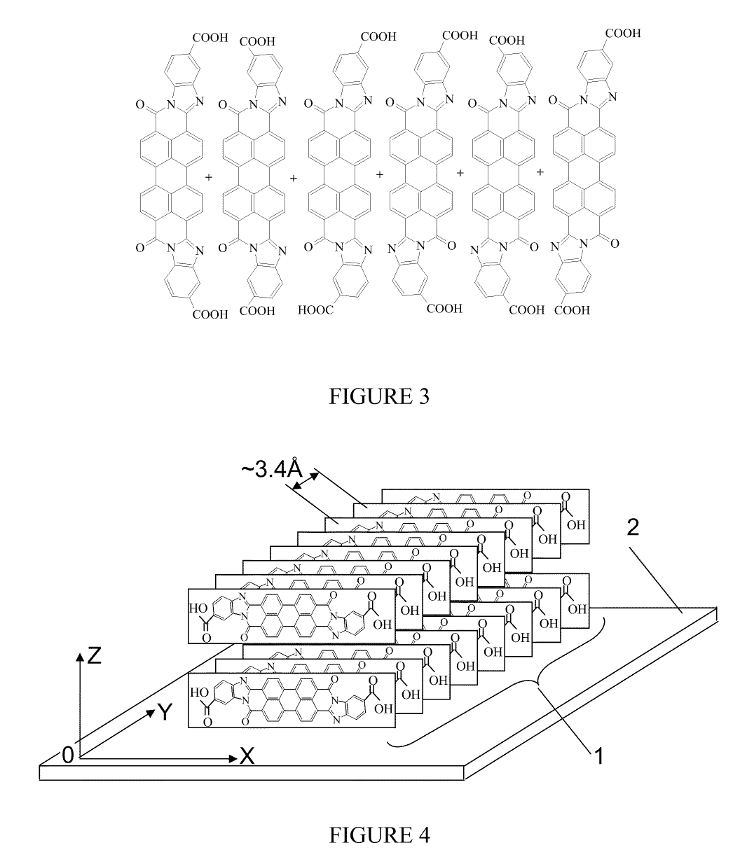

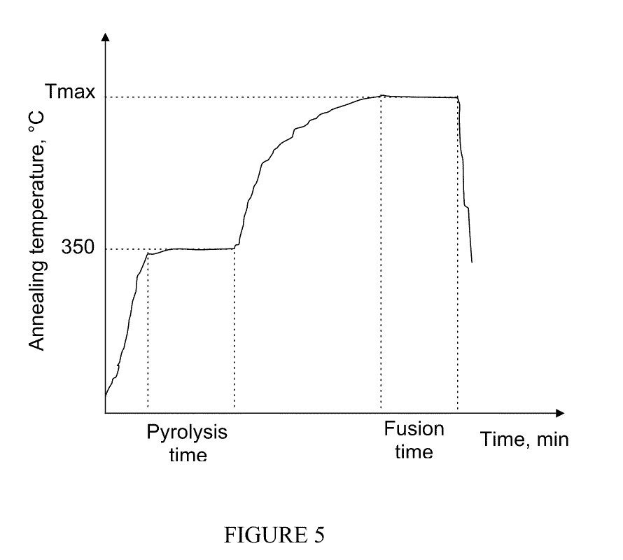

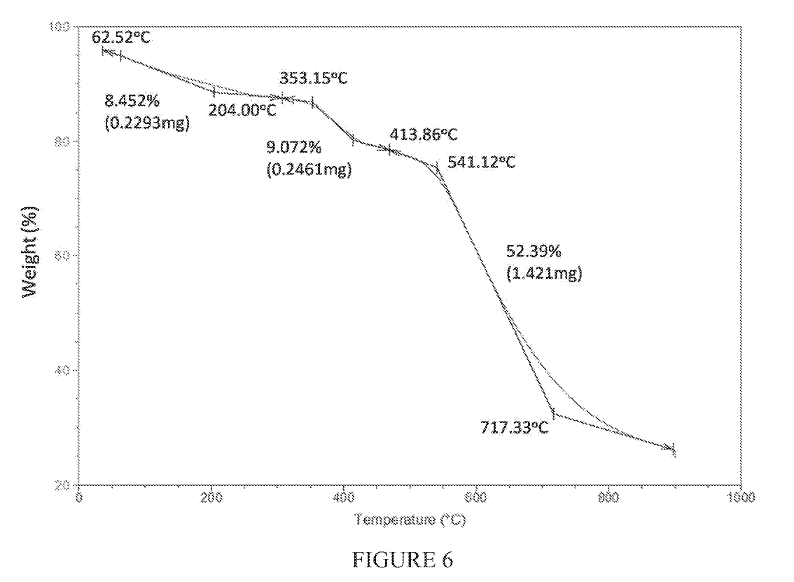

The example describes a formation of one embodiment of an interconnect system. The metallic ribtan layer comprising graphene-like carbon-based structures was formed by a mixture of bis(carboxybenzimidazoles) of prerylenetetracarboxylic acids (bis-carboxy DBI PTCA). As a first step, a water solution of bis-carboxy DBI PTCA was applied on a substrate. The solution comprises a mixture of six isomers as shown in FIG. 3. The predominantly planar polyaromatic cores are shown in Table 1, structures 4 and 5. Bis-carboxy DBI PTCA is a π-conjugated organic compound, where the predominantly planar carbon-conjugated core (CC in formula I) comprises rylene fragments. The benzimidazole groups serve as hetero-atomic groups, and carboxylic groups serve as substituents providing solubility. The molecular structure provides for the formation of rod-like molecular stacks. In this Example quartz glass was used as a substrate material. The Mayer rod technique was used to coat the water-based solution of bis-carboxy DBI PTCA. During the second step the drying was performed at 40 degrees C. and humidity of approximately 70%. At the end of the drying step, the layer usually retains about 10% of the solvent. As a result of the coating and drying steps the layer comprises rod-like supramolecules oriented along the coating direction. FIG. 4 schematically shows the supramolecule (1) oriented along the y-axis and located on the substrate (2). Distance between the planes of bis-carboxy DBI PTCA is approximately equal to 3.4 Å. The formation step was carried out in vacuum or inert gas. The step of formation of the metallic ribtan layer included two steps: 1) exposure of bis-carboxy DBI PTCA solid precursor layer at 350° C. for 30 minutes in order to carry out partial pyrolysis of the organic compound with at least partial removal of the hetero-atomic groups and the substituents from the layer, and 2) fusion in vacuum of the carbon-conjugated residues at 670° C. for 30 minutes in order to generate the predominantly planar graphene-like carbon-based structures. The typical time dependence of temperature during the formation step is shown in FIG. 5. At least part of the substituents S₁, S₂, S₃ and S₄ and hetero-atomic groups have been removed from the solid layer. After the formation step, thickness of the layer decreased to about 70% of the initial thickness. This value was essentially reproducible in the above referenced temperature ranges and time.

A thermo gravimetric analysis of the layer of bis-carboxy DBI PTCA is shown in FIG. 6. Thermal decomposition of bis-carboxy DBI PTCA has three main stages: 1) water and ammonia removal from the solid precursor layer (24-250° C.), 2) decarboxylation process (353-415° C.), and 3) removing of benzimidazoles with carbon-conjugated residues forming (541-717° C.). The formula weight (FW) of bis-carboxy BDI PTCA is shown in Table 6.

TABLE 6
Formula weight (FW) of bis-carboxy DBI PTCA

| Structure | FW | Loss, % |
|---|---|---|
| 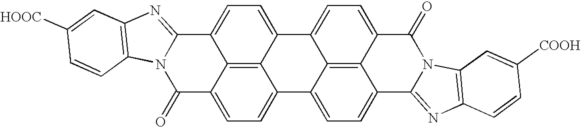 | 624.6 | 0 |
| 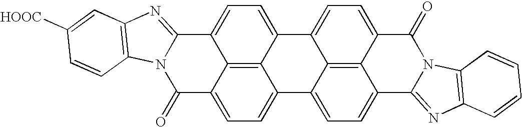 | 580.5 | 7.05 |
| 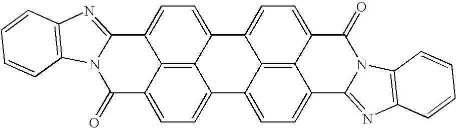 | 536.5 | 14.09 |
| 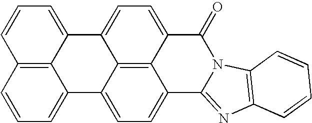 | 394.4 | 36.85 |
| 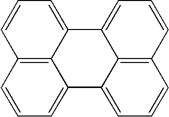 | 252.3 | 59.60 |

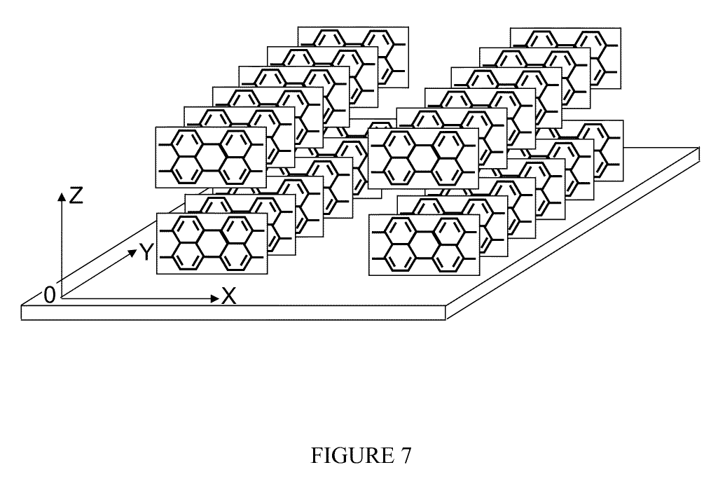

The resulting carbon-conjugated residues form the intermediate anisotropic structure represented in FIG. 7.

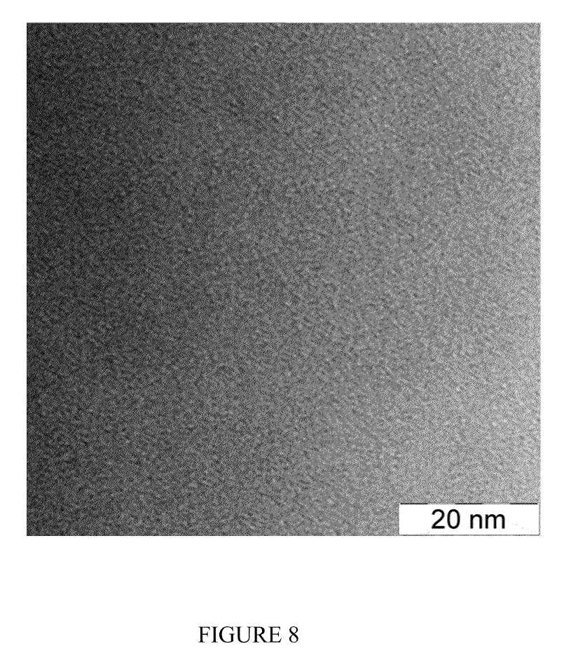

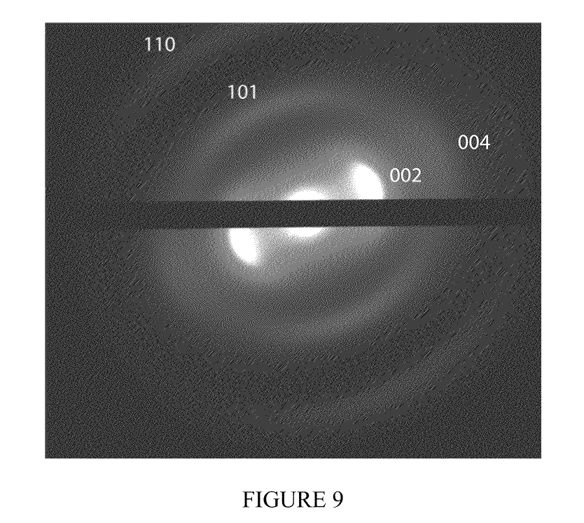

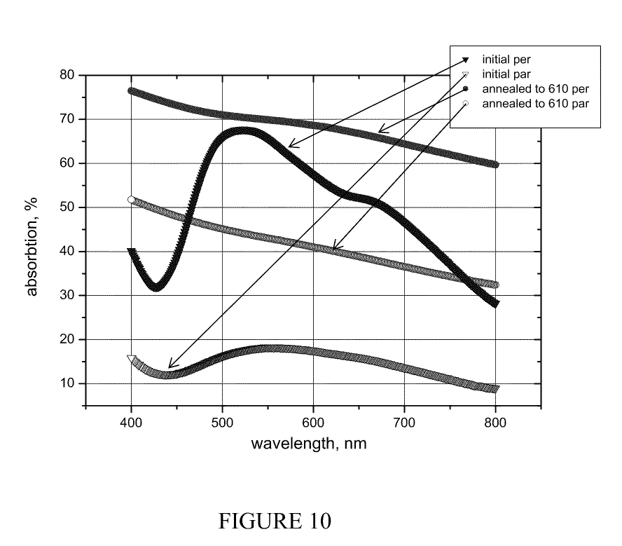

Further formation of the metallic ribtan layer results in the creation of predominantly planar graphene-like carbon-based structures via fusion of the carbon-conjugated residues under high temperatures. One possible embodiment of such graphene-like carbon-based structures is shown schematically in FIG. 1. FIG. 2 shows schematically the anisotropic ribtan layer (3) on the substrate (2) after the formation of the metallic ribtan layer. TEM image of the metallic ribtan layer formed on a substrate is shown in FIG. 8. There is global preferential orientation in the layer order. The orientation was also shown by electron diffraction images (FIG. 9). The diffraction image proves that the ribtan layer have layered structure similar to α-graphite. There are two clear maxima related to 002 and 00 2̅ diffraction reflexes that correspond to 1D ordering in the layer in the direction perpendicular to graphene planes. The interplanar space is about 3.4 Å. Absorption spectra in polarized light of the annealed and dried layer of bis-carboxy DBI PTCA are shown in FIG. 10. The absorption spectra of the initial samples and samples after formation of the metallic ribtan layer step (c) show an optical anisotropy.

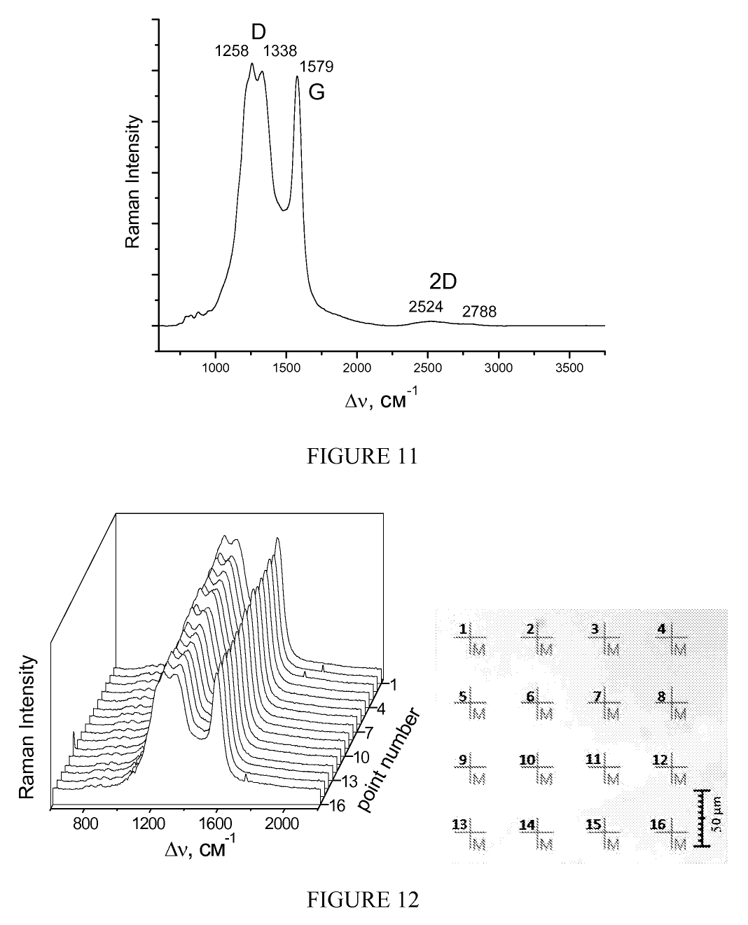

FIG. 11 shows Raman spectrum of the samples after formation step. The spectrum includes typical lines for sp² bonded carbon material. The position of these line G) and its FWHM suggests that the metallic ribtan layer consists of graphene-like layered structure. Lines D and 2D are split which means that the surface of ribtan layers consists of edges of graphene-like layers. Detection of Raman spectra in different points of the sample proves homogeneity of phase composition and distribution of structural defects over ribtan surface (FIG. 12).

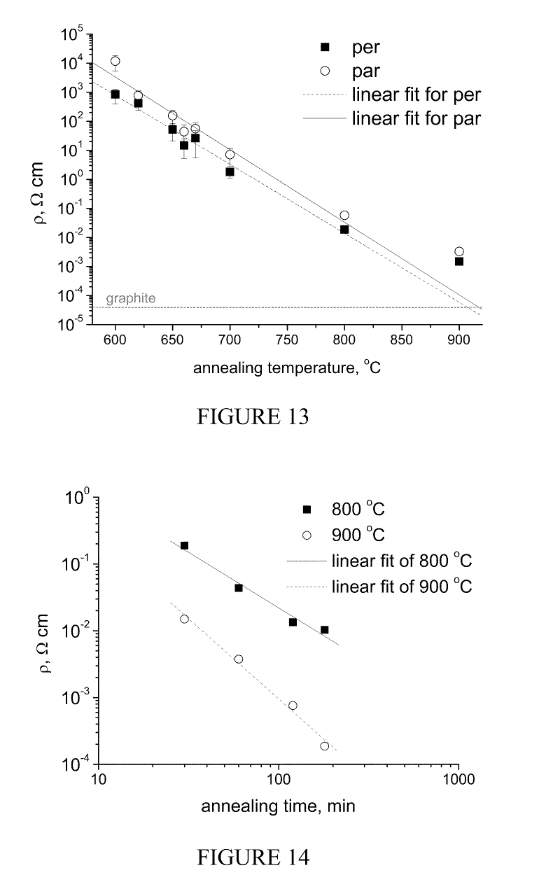

Measurements of resistivity of the metallic ribtan layers have been made using a standard 4-point probe technique. The resistivity of the metallic ribtan layers was measured parallel (par) and perpendicular (per) to coating direction in order to detect electrical anisotropy of the ribtan layers. Results of the measurements are shown in FIG. 13 and FIG. 14

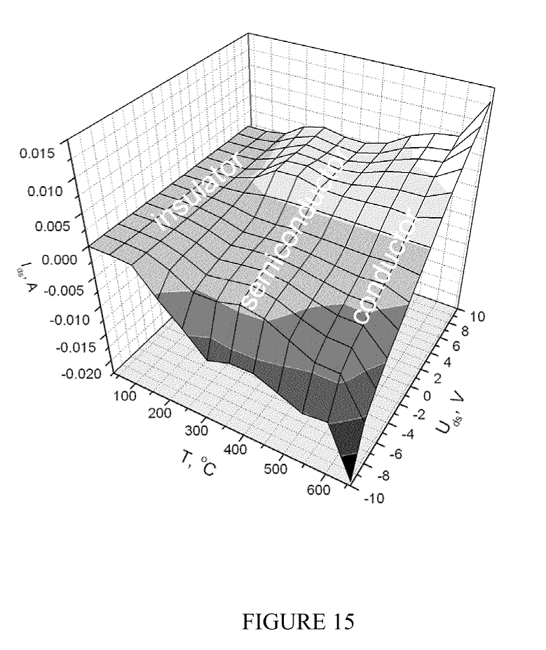

There is some anisotropy of resistivity along graphene-like nanoribbons (per) which is lower than resistivity across the nanoribbons (par). The resistivity strongly depends on fusion temperature and exposure time. FIG. 13 shows resistivity as a function of maximum fusion temperature (Tₘₐₓ) and FIG. 14 shows resistivity as a function of time of sample exposure at maximum temperature. Generally, resistivity decreases with increasing of exposure time and fusion temperature. The resistivity perpendicular to the coating direction is about 2-3 times smaller than resistivity parallel to the coating direction. Thus, the metallic ribtan layer possesses anisotropy of resistivity. Such anisotropy of the resistivity corresponds to a better charge transport in the direction along the graphene-like carbon-based structures. The voltage-current characteristics obtained at different annealing temperatures on bis-carboxy DBIPTCA layer is shown in FIG. 15. The metallic ribtan layers are characterized by dependence of conductivity (a reciprocal value of electrical resistivity) on fusion temperature and by transition: dielectric—semiconductor—conductor state. The high value of the measured conductivity proves the global (continuous) character of the metallic ribtan layer.

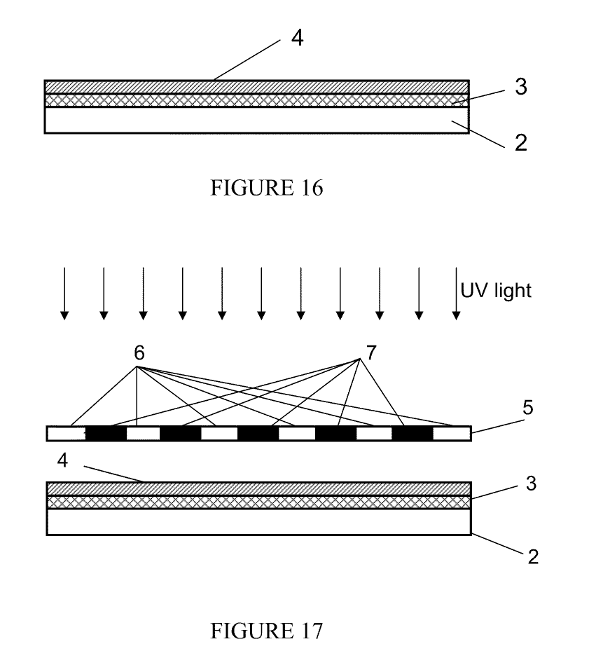

In this example the interconnect system was produced by photolithographic patterning of metallic ribtan layer. FIGS. 16-20 illustrate fabrication of the interconnect system in various patterning steps. The first step of patterning was formation of a HPR (positive) photoresist layer on the ribtan surface. The ribtan layer on a substrate was placed in a clean room, which was illuminated with yellow light, since photoresist is not sensitive to wavelengths greater than approximately 0.5 μm. The ribtan sample was held on a vacuum spindle, and a liquid resist was applied to the center of the sample. The structure was then rapidly accelerated up to a constant rotational speed 3000 rpm, which was maintained for 40 second. FIG. 16 schematically shows ribtan layer (3) on a substrate (2) coated by photoresist layer (4). As known to one skilled in the art, many variations may be used as methods of coating of samples with the photoresist layer. Spray coating, flooding, electrostatic method, and any other methods known in the art may be used.

After the spinning step, the multilayer structure was exposed to a soft bake (at 100° C. for 60 seconds) in order to remove the solvent from the photoresist layer and to increase adhesion of the photoresist to the ribtan layer.

The sample coated by photoresist layer was aligned with respect to the photomask in an optical lithographic system. The photomask has a pattern corresponding to a desired functional structure, and the photoresist was exposed to UV light through the mask during 120 seconds, as shown in FIG. 17. FIG. 17 schematically shows the multilayer structure comprising the substrate (2), the metallic ribtan layer (3), and the photoresist layer (4), and the mask (5). The mask (5) includes first translucent or transparent regions (6), and second opaque regions (7). The exposed photoresist relaxed in air at room temperature during about 1 minute. Then photoresist was dissolved in the mixture of HPR developer with DI water (1:3) during 70 seconds. The developed structure was then rinsed the flow of DI water during about 3 minutes and dried in nitrogen flow.

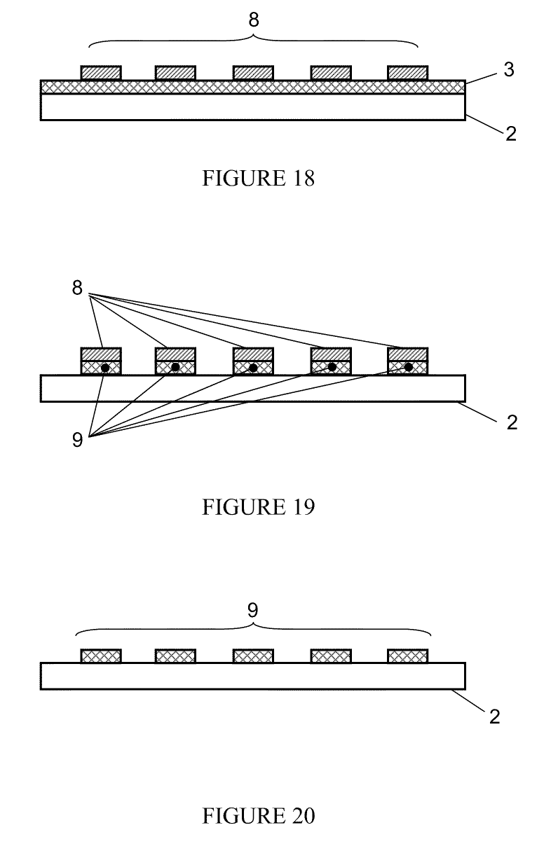

FIG. 18 shows the produced structure comprising the ribtan layer (3) and the patterned photoresist layer (8). The structure shown in FIG. 18 was then put in oxygen plasma that provides etching of the ribtan layer (3). FIG. 19 shows the patterned ribtan layer (9) with patterned photoresist layer (8). Then, the photoresist was dissolved in acetone, leaving in the ribtan layer (9) the pattern that was the same as the opaque regions (7) on the mask shown in FIG. 17.

Finally, the patterned metallic ribtan layer (9) has been formed on the substrate (2), as shown in FIG. 20.

### Example 12

This example describes a low-temperature method of producing a metallic ribtan layer on a substrate according to the present invention. The metallic ribtan layer comprising graphene-like carbon-based structures was formed by a mixture of bis(carboxybenzimidazoles) of prerylenetetracarboxylic acids (bis-carboxy DBIPTCA). As a first step, a water solution of bis-carboxy DBIPTCA was applied on a substrate. The solution comprised a mixture of six isomers as shown in FIG. 3, which predominantly planar carbon-conjugated cores are shown in Table 1, structures 4 and 5. Bis-carboxy DBIPTCA is a π-conjugated organic compound, where the predominantly planar carbon-conjugated core (CC in formula I) comprises rylene fragments, the benzimidazole groups serve as hetero-atomic groups, and carboxylic groups serve as substituents providing solubility. The molecular structure provides for the formation of rod-like molecular stacks. In this Example glass was used as a substrate material. The Mayer rod technique was used to coat the water-based solution of bis -carboxy DBIPTCA. During the second step drying was performed. By the end of the drying step, the layer usually retained about 10% of the solvent. As a result of the drying step the layer comprises rod-like supramolecules oriented along the coating direction. FIG. 4 schematically shows the supramolecule (1) oriented along the y-axis and located on the substrate (2). The distance between the planes of bis-carboxy DBIPTCA was approximately equal to 3.4 A.

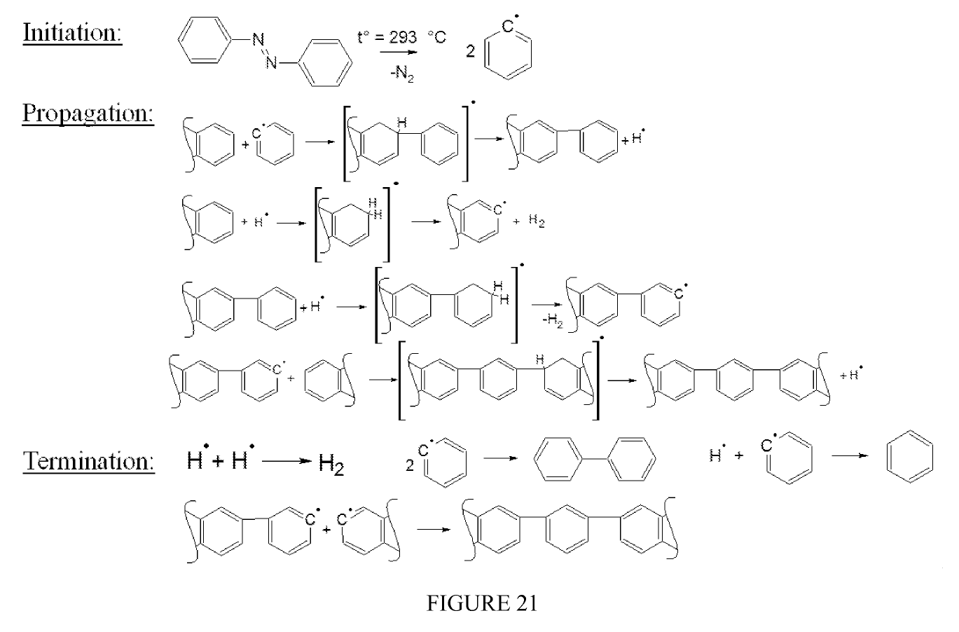

During the next step the solid layer was placed into a gas-phase environment containing molecules which were sources of free radicals or benzyne fragments. In this example azobenzene C₆H₅N₂C₆H₅ was used as a source of free benzene radicals in gas phase. Heating up to 300° C. was used for evaporation of azobenzene and formation of benzene free radicals. The chemical reactions taken place in the reactor are schematically shown in the FIG. 21. Radical induced polymerization occurred. The process of the radical polymerization consisted of three main steps which were initiation step, propagation step and termination step. Free benzene radicals arose during an initiation step which was decomposition of azobenzene. The reaction was thermally activated and the temperature of the azobenzene decomposition was not higher than 300 degrees C. The free benzene radicals reacted with polyaromatic precursor molecules in the solid layer via substitution reaction: one hydrogen atom of polyaromatic core was substituted by one benzene ring, through a homolytic pathway. The reaction led to closing of gaps with benzene between aligned discotic precursor molecules in a solid precursor layer and formation of free hydrogen radicals. The resulting free hydrogen radical reacted with carbon conjugated cores and caused formation of free radicals on polyaromatic cores of precursor molecules. Due to global alignment of rod-like supramolecules in the solid precursor layer and addition of benzene radicals to the polyaromatic cores the neighbour discotic molecules with formed free radicals on their edges were ready for the joint reaction. Hence conjugation of the precursor molecules with covalent Csp²-Csp² bonds into graphene-like carbon-based structures was propagated in the ribtan layer and formation of metallic ribtan layer takes place at low temperature (not much higher than 300° C.). The free radicals could annihilate with each other and disappear from the reaction during termination step.

The above described embodiments are given as illustrative examples only. It will be readily appreciated that many deviations may be made from the specific embodiments disclosed in this specification without departing from the invention. Accordingly, the scope of the invention is to be determined by the claims below rather than being limited to the specifically described embodiments above.

What is claimed is:

1. An integrated circuit comprising
a substrate,
a set of circuit elements that are formed on the substrate, and
an interconnect system that interconnects the circuit elements,
wherein at least part of the interconnect system is made of a metallic ribtan material.

2. An integrated circuit according to claim 1, wherein the interconnect system comprises an interconnector selected from the list comprising a direct interconnector, capacitive interconnector, and inductive interconnector.

3. An integrated circuit according to claim 1, wherein the circuit elements are formed on one surface or on both surfaces of the substrate.

4. An integrated circuit according to claim 1, wherein the substrate is made of one or several materials of the group comprising Si, Ge, SiGe, GaAs, diamond, quartz, silicon carbide, indium arsenide, indium phosphide, silicon germanium carbide, gallium arsenic phosphide, gallium indium phosphide, plastics, glasses, ceramics, metal-ceramic composites, metals, and comprises doped regions, circuit elements, and multilevel interconnects, wherein said plastic substrate is selected from the group comprising polycarbonate, Mylar, polyethylene terephthalate (PET) and polyimide.

5. An integrated circuit according to claim 1, wherein at least one circuit element is selected from the list comprising an active circuit element and a passive circuit element, wherein the active circuit element is selected from the list comprising a transistor, diode, and monolithic device, and the passive circuit element is selected from the list comprising an inductor, resistor, capacitor, radio frequency (Rf) antenna, magnetic coupling, transformer, plurality of input pads, and plurality of output pads.

6. An integrated circuit according to claim 1, wherein the integrated circuit performs one or more functions selected from the list comprising electrical, optical, optoelectronic, and passive functions.

7. An integrated circuit according to claim 1, wherein the metallic ribtan material is prepared using a solution comprising at least one π-conjugated organic compound of the general structural formula I or a combination of the organic compounds of the general structural formula I: 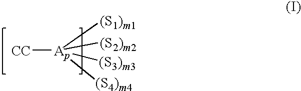
where CC is a predominantly planar carbon-conjugated core;
A is a hetero-atomic group;
p is 0, 1, 2, 3, 4, 5, 6, 7, or 8;
S₁, S₂, S₃, and S₄ are substituents,
m1, m2, m3 and m4 are 0, 1, 2, 3, 4, 5, 6, 7, or 8; and
sum (m1+m2+m3+m4) is 1, 2, 3, 4, 5, 6, 7, 8, 9 or 10.

8. An integrated circuit according to claim 7, wherein said organic compound comprises one or more rylene fragments having a general structural formula selected from the group comprising structures 1-23:

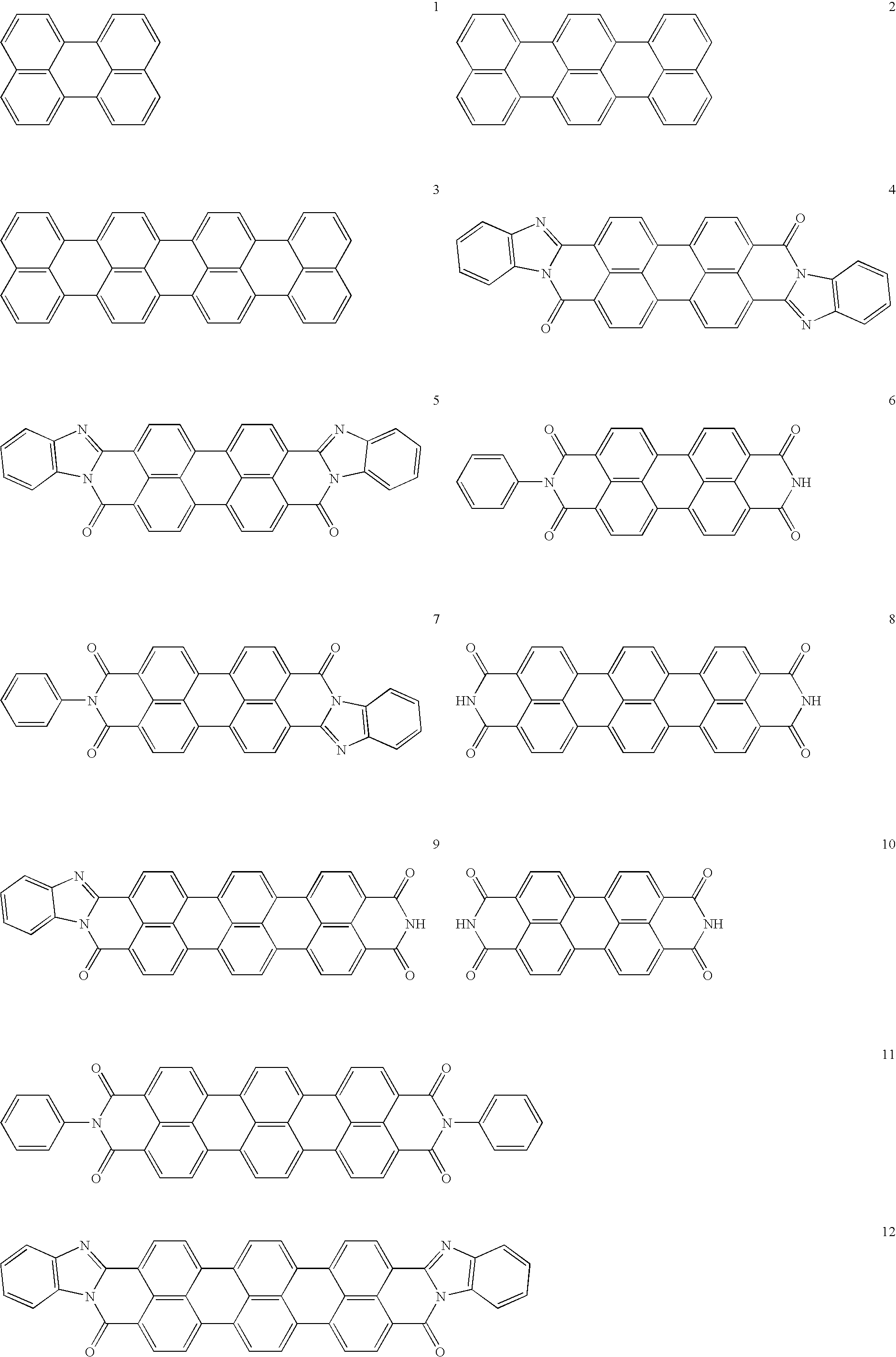

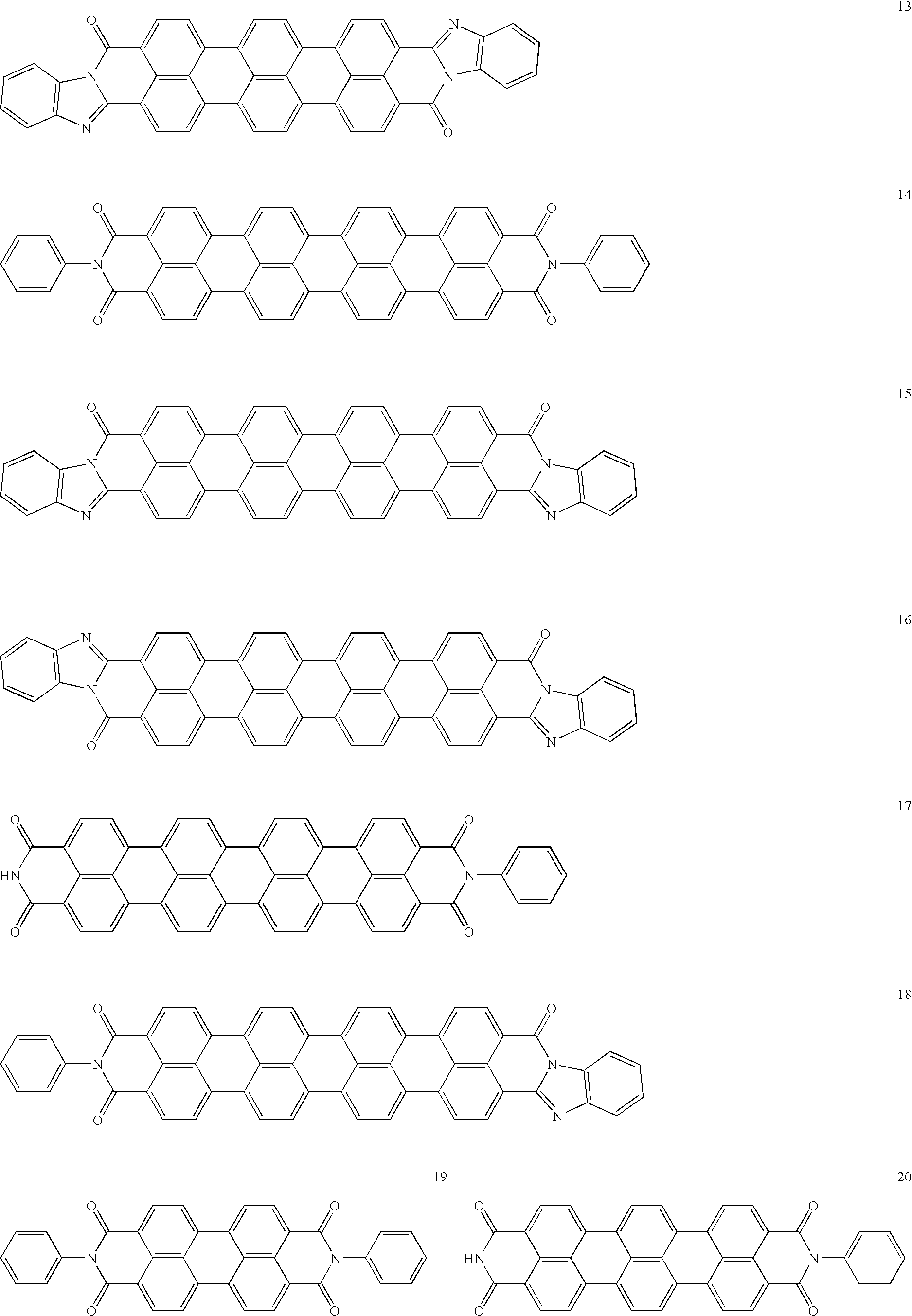

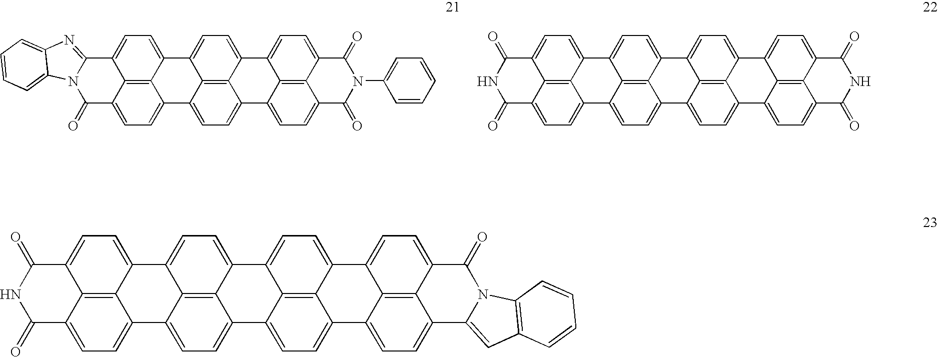

9. An integrated circuit according to claim 7, wherein said organic compound comprises one or more anthrone fragments having a general structural formula selected from the group comprising structures 24-31:

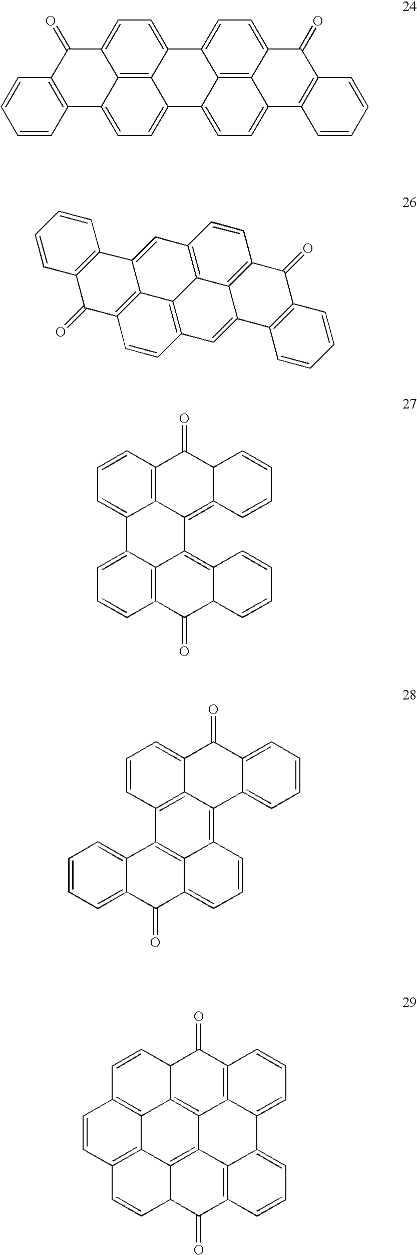

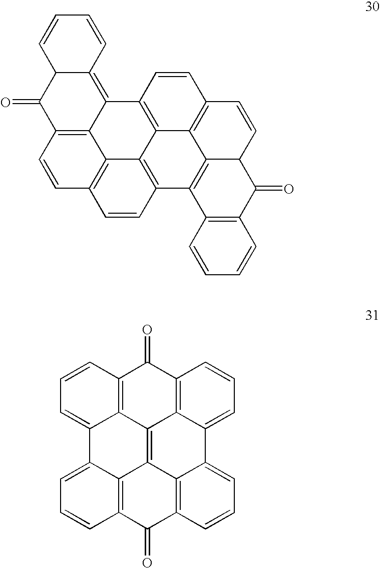

10. An integrated circuit according to claim 7, wherein said organic compound comprises fused polycyclic hydrocarbons selected from the list comprising truxene, decacyclene, antanthrene, hexabenzotriphenylene, 1,2,3,4,5,6,7,8-tetra-(peri-naphthylene)-anthracene, dibenzoctacene, tetrabenzoheptacene, peropyrene, hexabenzocoronene, violanthrene, isoviolanthrene having a structure selected from the group consisting of structure 32-43:

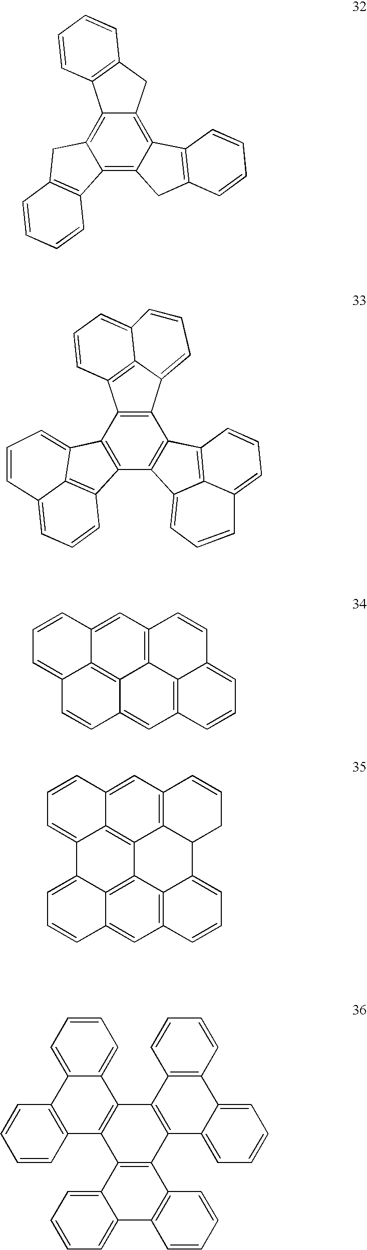

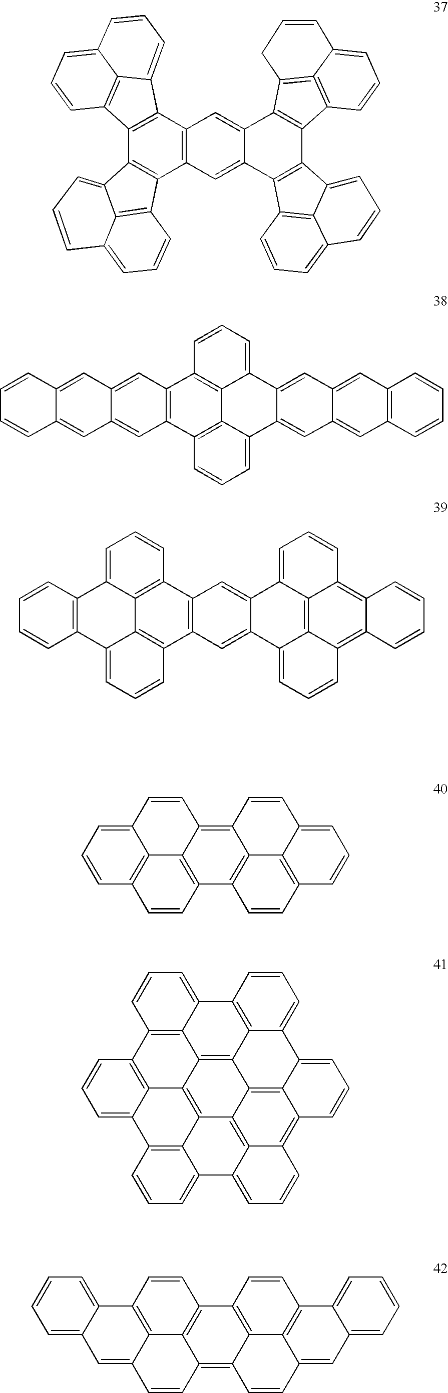

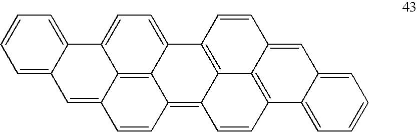

11. An integrated circuit according to claim 7, wherein said organic compound comprises one or more coronene fragments having a general structural formula selected from the group comprising structures 44-51:

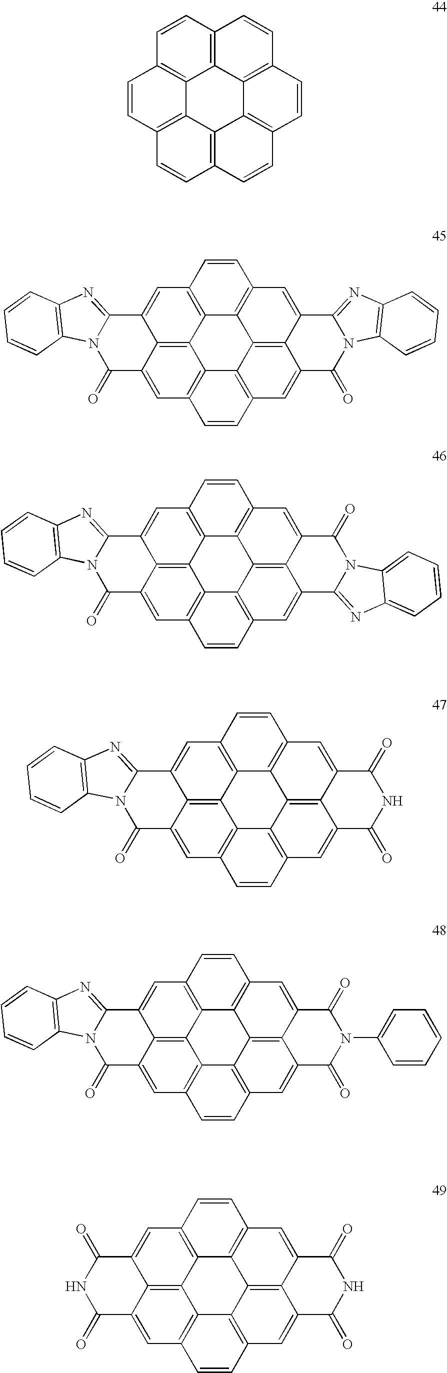

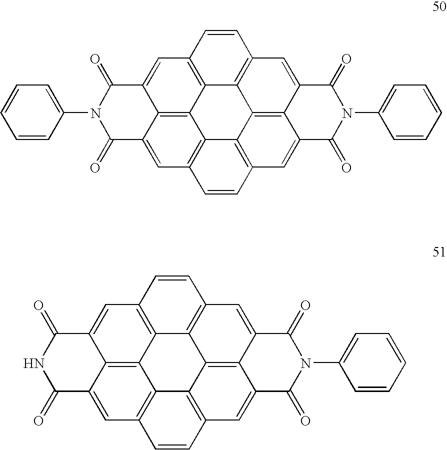

12. An integrated circuit according to claim 7, wherein the metallic ribtan material is prepared using a mixture of bis(carboxybenzimidazoles) of prerylenetetracarboxylic acids (bis-carboxy DBI PTCA).

13. A method of producing a metallic ribtan layer on a substrate, which comprises the following steps:
(a) application of a solution of at least one π-conjugated organic compound of a general structural formula I or a combination of the organic compounds of the general structural formula I on the substrate: 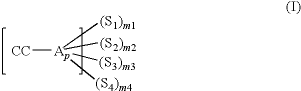
where CC is a predominantly planar carbon-conjugated core;
A is a hetero-atomic group;
p is 0, 1, 2, 3, 4, 5, 6, 7, or 8;
S₁, S₂, S₃, and S₄ are substituents,
m1, m2, m3 and m4 are 0, 1, 2, 3, 4, 5, 6, 7, or 8; and
sum (m1+m2+m3+m4) is 1, 2, 3, 4, 5, 6, 7, 8, 9 or 10;
(b) drying with formation of a solid precursor layer, and
(c) formation of a metallic ribtan layer,
wherein said formation step is characterized by a level of vacuum, a composition and pressure of ambient gas, and a time dependence of temperature which are selected so as to ensure a creation of predominantly planar graphene-like structures in the metallic ribtan layer,
wherein at least one said graphene-like structure possesses conductivity and is predominantly continuous within the entire metallic ribtan layer, and wherein thickness of the metallic ribtan layer is in the range from approximately 1 nm to 1000 nm.

14. A method according to claim 13, wherein the predominantly planar carbon-conjugated core (CC), the substituents S₁, S₂, S₃, and S₄, and coating conditions are selected so that the graphene-like structures have a form of planar graphene-like nanoribbons, the planes of which are oriented predominantly perpendicularly to the substrate surface.

15. A method according to claim 13, wherein the predominantly planar carbon-conjugated core (CC), the substituents S₁, S₂, S₃, and S₄, and coating conditions are selected so that the graphene-like structures have a form of planar graphene-like sheets the planes of which are oriented predominantly parallel to the substrate surface.

16. A method according to claim 13, wherein the drying and formation steps are carried out simultaneously or sequentially.

17. A method according to claim 13, wherein the ambient gas comprises chemical elements selected from the list comprising hydrogen, nitrogen, fluorine, arsenic, boron, carbon tetrachloride, halogens, halogenated hydrocarbons, and any combination thereof.

18. A method according to claim 13, further comprising a post-treatment in a gas atmosphere, wherein the post-treatment step is carried out after the formation step and wherein the gas atmosphere comprises chemical elements selected from the list comprising hydrogen, nitrogen, fluorine, arsenic, boron, carbon tetrachloride, halogens, halogenated hydrocarbons, and any combination thereof.

19. A method according to claim 13, further comprising a doping step carried out after the formation step and/or after the post-treatment step and during which the metallic ribtan layer is doped with impurities, wherein the doping step is based on a method selected from the list comprising diffusion method, intercalation method and ion implantation method, and wherein the impurity is selected from the list comprising Sb, P, As, Ti, Pt, Au, O, B, Al, Ga, In, Pd, S, F, N, Br, I and any combination thereof.

20. A method according to claim 13, wherein at least one of the hetero-atomic groups is selected from the list comprising imidazole group, benzimidazole group, amide group, and substituted amide group.

21. A method according to claim 13, wherein said solution is based on water and wherein at least one of the substituents providing solubility of the organic compound is selected from the list comprising COO⁻, SO₃⁻, HPO₃⁻, and PO₃²⁻, and any combination thereof.

22. A method according to claim 13, wherein said solution is based on an organic solvent and wherein the organic solvent is selected from the list comprising ketones, carboxylic acids, hydrocarbons, cyclohydrocarbons, chlorohydrocarbons, alcohols, ethers, esters, acetone, xylene, toluene, ethanol, methylcyclohexane, ethyl acetate, diethyl ether, octane, chloroform, methylenechloride, dichloroethane, trichloroethene, tetrachloroethene, carbon tetrachloride, 1,4-dioxane, tetrahydrofuran, pyridine, triethylamine, nitromethane, acetonitrile, dimethylformamide, dimethulsulfoxide, and any combination thereof, and wherein at least one of the substituents providing solubility of the organic compound in the organic solvent is selected from the list comprising linear and branched (C₁-C₃₅)alkyl, (C₂-C₃₅)alkenyl, and (C₂-C₃₅)alkinyl, an amide of an acid residue independently selected from the list comprising CONR₁R₂, CONHCONH₂, SO₂NR₁R₂, R₃, fragments selected from the list comprising structures 52-58 and any combination thereof, where R₁, R₂ and R₃ are independently selected from the list comprising hydrogen, a linear alkyl group, a branched alkyl group, an aryl group, and any combination thereof, where the alkyl group has the general formula —(CH₂)ₙCH₃, where n is an integer from 0 to 27, and the aryl group is selected from the group comprising phenyl, benzyl and naphthyl: 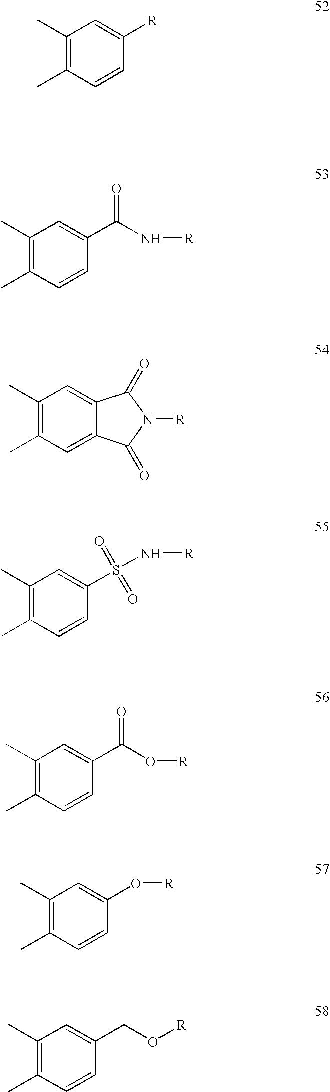
where R is selected from the list comprising linear or branched (C₁-C₃₅) alkyl, (C₂-C₃₅)alkenyl, and (C₂-C₃₅)alkinyl.

23. A method according to claim 13, wherein said drying stage is carried out using an airflow.

24. A method according to 13, further comprising a pre-treatment of the substrate prior to the application of said solution so as to render its surface hydrophilic.

25. A method according to claim 13, wherein a type of said solution is selected from the list comprising an isotropic solution and a lyotropic liquid crystal solution.

26. A method according to claim 13, further comprising an alignment action, wherein the alignment action is simultaneous or subsequent to the application of said solution on the substrate.

27. A method according to claim 13, wherein said application stage is carried out using a technique selected from the list comprising a spray-coating, Mayer rod technique, blade coating, slot-die application, extrusion, roll coating, curtain coating, knife coating and printing.

28. A method according to claim 13, wherein the π-conjugated organic compound further comprises molecular binding groups which number and arrangement thereof provide for the formation of planar supramolecules from the organic compound molecules in the solution via non-covalent chemical bonds, wherein at least one said binding group is selected from the list comprising hetero-atoms, COOH, SO₃H, H₂PO₃, NH, NH₂, CO, OH, NHR, NR, COOMe, CONH₂, CONHNH₂, SO₂NH₂, —SO₂—NH—SO₂—NH₂, and any combination thereof, a hydrogen acceptor (A_{H}), a hydrogen donor (D_{H}), and a group having a general structural formula 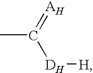
where radical R is independently selected from the list comprising a linear alkyl group, branched alkyl group, aryl group, and any combination thereof, where the alkyl group has a general formula —(CH₂)ₙCH₃, where n is an integer from 0 to 27, and where the aryl group is selected from the group comprising phenyl, benzyl and naphthyl and wherein the hydrogen acceptor (A_{H}) and hydrogen donor (D_{H}) are independently selected from the list comprising NH-group, and oxygen (O), wherein the non-covalent chemical bonds are independently selected from the list comprising a single hydrogen bond, dipole-dipole interaction, cation—pi-interaction, Van-der-Waals interaction, coordination bond, ionic bond, ion-dipole interaction, multiple hydrogen bond, interaction via the hetero-atoms, and any combination thereof and wherein the planar supramolecule have the form selected from the list comprising disk, plate, lamella, ribbon, and any combination thereof.

29. A method according to claim 28, wherein the planar supramolecules are predominantly oriented in the plane of the substrate.

30. A method according to claim 13, wherein the formation step is carried out in vacuum or inert gas.

31. A method according to claim 13, wherein the formation step is carried out as process of annealing so as to ensure 1) partial pyrolysis of the organic compound with at least partial removing of substituents, hetero-atomic and solubility groups from the solid precursor layer, and 2) fusion of the carbon-conjugated residues.

32. A method according to claim 31, wherein the pyrolysis temperature is in the range between approximately 150 and 650 degrees C., and the fusion temperature is in the range between approximately 500 and 2500 degrees C.

33. A method according to claim 13, wherein the formation step is carried out without heating or under moderate heating (less than 500 degrees C.) under the action of gas-phase or liquid phase environment containing molecules which are sources of free radicals or benzyne fragments.

34. A method according to claim 33, wherein the said formation step is further accompanied by applying an external action upon the metallic ribtan layer stimulating low-temperature carbonization process and formation of the graphene-like carbon-based structures.

35. A method according to claim 13, further comprising the step of removing the substrate by one of the methods selected from the list comprising wet chemical etching, dry chemical etching, plasma etching, laser etching, grinding, and any combination thereof.

36. A method according to claim 13, wherein number of the substituents S1, S2, S3, and S4 providing solubility of the organic compound is equal or more than 2 and the substituents are the same or at least one said substituent is different from other or others.

37. A method according to claim 13, wherein the steps (a), (b) and (c) are consecutively repeated two or more times, and sequential metallic ribtan layers are formed using solutions based on the same or different organic compounds or their combinations.

38. A method of producing a metallic ribtan layer on a substrate, which comprises the following steps:
(a) preparation of a solution of one π-conjugated organic compound of a general structural formula II or a combination of the organic compounds of the general structural formula II capable of forming supramolecules: 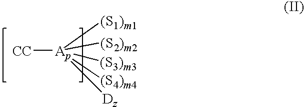
where CC is a predominantly planar carbon-conjugated core;
A is an hetero-atomic group;
p is 0, 1, 2, 3, 4, 5, 6, 7, or 8;
S₁, S₂, S₃, S₄ and D are substituents,
where S₁, S₂, S₃, and S₄ are substituents providing solubility of the organic compound in a suitable solvent and
D is a substituent which produces reaction centers selected from the list comprising free radicals and benzyne fragments on the predominantly planar carbon-conjugated cores after a subsequent elimination of this substituent during a step (e);
m1, m2, m3 and m4 are 0, 1, 2, 3, 4, 5, 6, 7, or 8;
sum (m1+m2+m3+m4) is 1, 2, 3, 4, 5, 6, 7, 8, 9 or 10; and
z is 0, 1, 2, 3 or 4;
(b) deposition a layer of the solution on the substrate;
(c) an alignment action upon the solution in order to ensure a preferred alignment of the supramolecules;
(d) drying with formation of a solid precursor layer; and
(e) application of an external action upon the solid layer stimulating low-temperature carbonization and formation of a metallic ribtan layer.

39. A method according to claim 38, wherein the substituent D is selected from the list comprising halogens Cl, Br and I.

40. A method according to claim 38, wherein said deposition step is carried out using a technique selected from the list comprising a spray-coating, Mayer rod technique, blade coating, slot-die application, extrusion, roll coating, curtain coating, knife coating, and printing.

41. A method according to claim 38, wherein the alignment action upon the surface of the solution layer is produced by a technique selected from the list comprising a directed mechanical motion of at least one aligning instrument selected from the list comprising a knife, cylindrical wiper, flat plate and any other instrument oriented parallel to the deposited solution layer surface, whereby a distance from the substrate surface to the edge of the aligning instrument is preset so as to obtain a solid precursor layer; a heated instrument, application of an external electric field to the deposited solution layer, application of an external magnetic field to the deposited solution layer, application of an external electric and magnetic field to the deposited solution layer, with simultaneous heating, illuminating the deposited solution layer with at least one coherent laser beams, and any combination of the above listed techniques.

42. A method according to claim 38, wherein the external action is selected from the list comprising a thermal treatment and ultraviolet irradiation.

43. A method according to claim 42, wherein the thermal treatment is carried out at the temperature not exceeding the melting temperature of a substrate material.

44. A method according to claim 38, further comprising a post-treatment step of placement the solid layer into a gas phase environment containing molecules being sources of free radicals or benzyne fragments, wherein the post-treatment step is carried out after the drying step.
